(19) United States
(12) Patent Application Publication
(10) Pub. No.: US 2026/0305268 A1
(43) Pub. Date: Oct. 1, 2026

(54) METHOD OF FORMING PATTERN AND METHOD OF MANUFACTURING SEMICONDUCTOR DEVICE

(71) Applicant: Samsung Electronics Co., Ltd., Suwon-si (KR)

(72) Inventors: Seok Hwan LEE, Suwon-si (KR); Yunho KIM, Suwon-si (KR); Younghun KIM, Suwon-si (KR); Samjong CHOI, Suwon-si (KR)

(73) Assignee: Samsung Electronics Co., Ltd., Suwon-si (KR)

(21) Appl. No.: 19/364,682

(22) Filed: Oct. 21, 2025

(30) Foreign Application Priority Data
Mar. 31, 2025 (KR) 10-2025-0041443

(51) Int. Cl. H01L 21/033; H01L 21/3213

(52) U.S. Cl. CPC H10P 76/4083; H10P 50/71; H10P 76/405

(57) ABSTRACT

A method of manufacturing a semiconductor device may include forming resist patterns on a substrate, coating a precursor on the resist patterns to form a preliminary metal oxide layer, the precursor being in a state of one of a solution, a sol, or a gel, solidifying the preliminary metal oxide layer to form a metal oxide layer, and recessing the metal oxide layer to form a metal oxide pattern exposing top surfaces of the resist patterns, wherein the resist patterns include a metal oxide, an oxygen content in the metal oxide pattern is greater than an oxygen content in the resist patterns, and the metal oxide pattern is arranged between the resist patterns.

### CROSS-REFERENCE TO RELATED APPLICATION

This application is based on and claims priority under 35 U.S.C. § 119 to Korean Patent Application No. 10-2025-0041443, filed on Mar. 31, 2025, in the Korean Intellectual Property Office, the disclosure of which is incorporated by reference herein in its entirety.

### BACKGROUND

Some example embodiments of the inventive concepts relate to methods of forming a pattern, and/or more particularly, to methods of manufacturing a semiconductor device using the methods of forming a pattern.

As the electronics industry develops, the demand for higher integration of semiconductor devices is becoming increasingly intense. Accordingly, various problems in the patterning process that forms fine patterns have arisen, making the implementation of semiconductor devices increasingly difficult. In addition, the patterning process becomes more complex and/or the efficiency of the patterning process decreases.

### SUMMARY

Some example embodiments of the inventive concepts provide methods of forming a pattern with improved process productivity and/or methods of manufacturing a semiconductor device including the same.

Some example embodiments of the inventive concepts also provide methods of forming a pattern with a relatively fine pitch.

According to an example embodiment of the inventive concepts, a method of manufacturing a semiconductor device may include forming resist patterns on a substrate, coating a precursor on the resist patterns to form a preliminary metal oxide layer, the precursor being in a state of one of a solution, a sol, or a gel, solidifying the preliminary metal oxide layer to form a metal oxide layer, and recessing the metal oxide layer to form a metal oxide pattern exposing top surfaces of the resist patterns, wherein the resist patterns include metal oxide, an oxygen content in the metal oxide pattern is greater than an oxygen content in the resist patterns, and the metal oxide pattern is arranged between the resist patterns.

According to an example embodiment of the inventive concepts, a method of forming a pattern may include forming a resist pattern including a metal oxide on a substrate, forming spacers on sidewalls of the resist pattern, forming a preliminary metal oxide layer to cover the spacers by coating the resist pattern and the spacers with a precursor, the precursor being in a state of one of a solution, a sol, or a gel, solidifying the preliminary metal oxide layer to form a metal oxide layer, and recessing the metal oxide layer to form a metal oxide pattern exposing a top surface of the resist pattern, wherein the metal oxide pattern is laterally spaced apart from the resist pattern, and a metal content in the metal oxide pattern is less than a metal content in the resist pattern.

According to an example embodiment of the inventive concepts, a method of forming a pattern may include forming an etching target layer on a substrate, forming an upper layer on the etching target layer, forming resist patterns including metal oxide on the upper layer, performing a coating process using a precursor in a solution, sol, or gel state to form a preliminary metal oxide layer between the resist patterns, solidifying the preliminary metal oxide layer to form a metal oxide layer, removing the metal oxide layer on top surfaces of the resist patterns to form a metal oxide pattern, and performing an etching process using the resist patterns and the metal oxide pattern as an etching mask.

### BRIEF DESCRIPTION OF THE DRAWINGS

Some example embodiments will be more clearly understood from the following detailed description taken in conjunction with the accompanying drawings in which:

FIGS. 1A to 8D are diagrams illustrating a method of forming a pattern, according to an example embodiment;

FIGS. 9A to 13D are diagrams illustrating a method of forming a pattern, according to an example embodiment;

FIGS. 14A to 14E are diagrams illustrating a method of forming a pattern, according to an example embodiment;

FIGS. 15A to 15C are diagrams illustrating a method of forming a pattern, according to an example embodiment;

FIGS. 16A to 16H are diagrams illustrating a method of forming a pattern, according to an example embodiment;

FIGS. 17A and 17B are diagrams illustrating a method of forming a pattern, according to an example embodiment;

FIGS. 18A and 18B are diagrams illustrating a method of forming a pattern, according to an example embodiment;

FIG. 18C is a diagram illustrating a method of forming a pattern, according to an example embodiment;

FIGS. 19A to 19E are diagrams illustrating a method of forming a pattern, according to an example embodiment; and

FIGS. 20A to 20C are diagrams illustrating a method of forming a pattern, according to an example embodiment.

### DETAILED DESCRIPTION

Herein, the same reference numerals may refer to the same components. Hereinafter, methods of forming a pattern and methods of manufacturing a semiconductor device are described, according to some example embodiments. The method of manufacturing a semiconductor device according to some example embodiments may include the method of forming a pattern. A process of forming a pattern may be referred to as a patterning process.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

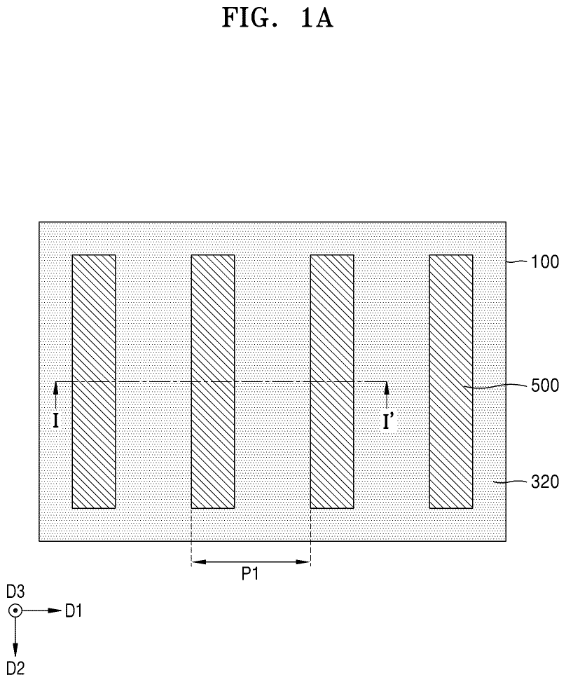

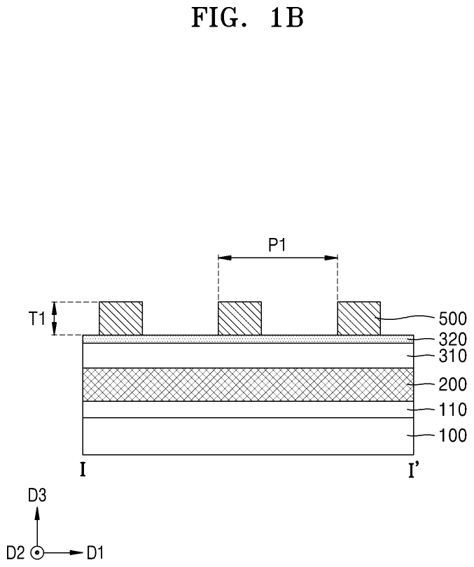

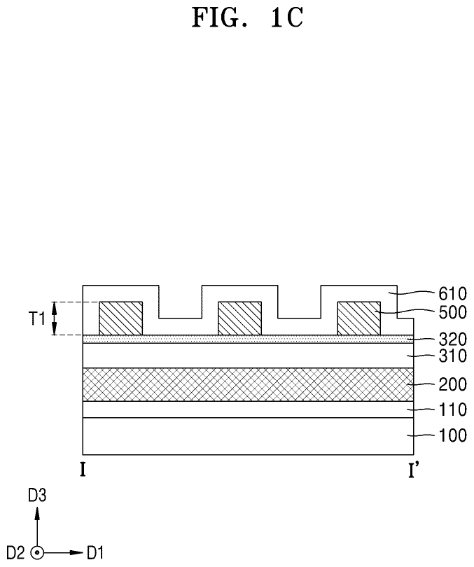

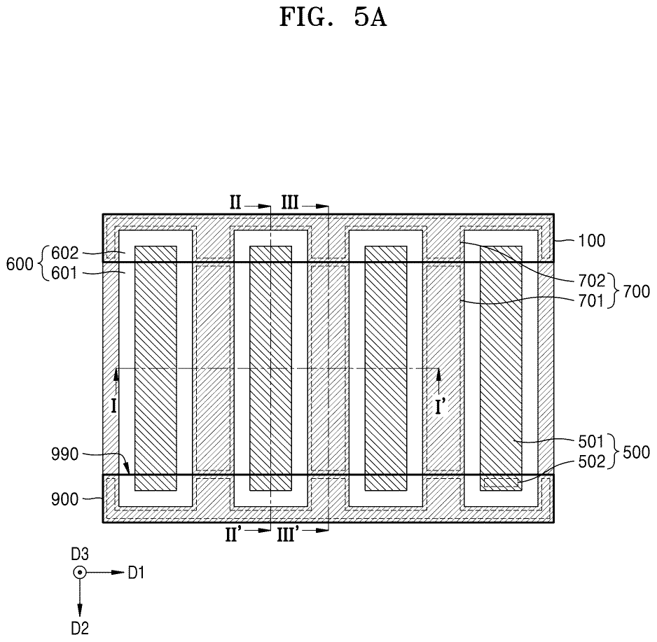

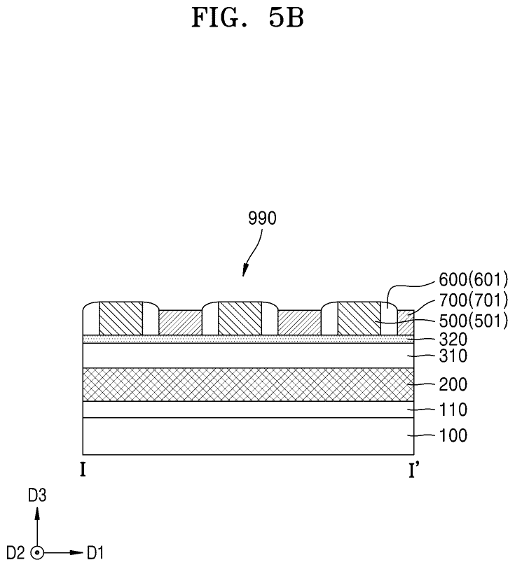

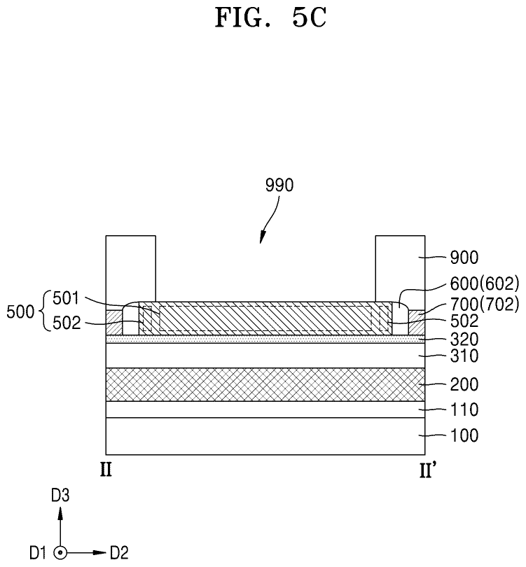

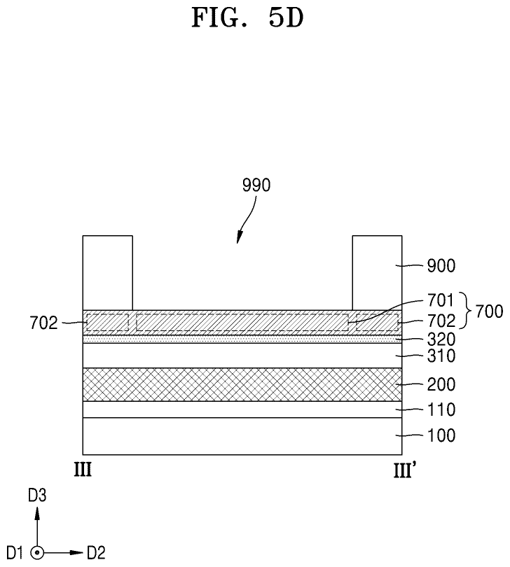

FIGS. 1A to 8D are diagrams illustrating a method of forming a pattern, according to an example embodiment. FIGS. 1A, 2A, 3A, 4A, 5A, 6A, 7A, and 8A are plan views illustrating a method of forming a pattern, according to an example embodiment. FIGS. 1B, 2B, 3B, 4B, 5B, 6B, 7B, and 8B are cross-sectional views taken along line I-I′ of FIGS. 1A, 2A, 3A, 4A, 5A, 6A, 7A, and 8A, respectively. FIGS. 5C, 6C, 7C, and 8C are cross-sectional views taken along line II-II′ of FIGS. 5A, 6A, 7A, and 8A, respectively. FIGS. 5D, 7D, and 8D are cross-sectional views taken along line III-III′ of FIGS. 5A, 7A, and 8A, respectively.

Referring to FIGS. 1A and 1B, a substrate 100, where a lower layer 110, an etching target layer 200, an upper layer, and a resist pattern 500 are stacked, may be prepared. The substrate 100 may include a semiconductor substrate or a semiconductor wafer.

The lower layer 110 may be formed on a top surface of the substrate 100. The lower layer 110 may include a transistor, conductive wires, and a combination thereof. The lower layer 110 may include an insulating material, a semiconductor material, a conductive material, and/or a combination thereof.

The etching target layer 200 may be formed on a top surface of the lower layer 110. In an example, the etching target layer 200 may include a conductive material. The conductive material may include conductive metal nitride, metal, metal-semiconductor compound, and/or a combination thereof. The conductive metal nitride may include titanium nitride and/or tantalum nitride. The metal may include tungsten (W), copper (Cu), aluminum (Al), titanium (Ti), ruthenium (Ru), molybdenum (Mo), and/or tantalum (Ta). The metal-semiconductor compound may include tungsten silicide, cobalt silicide, and titanium silicide. In some example embodiments, the conductive material may include hafnium oxide, zirconium oxide, and/or a combination thereof. As another example, the etching target layer 200 may include a semiconductor material, an insulating material, and/or a combination thereof. For example, the semiconductor material may include silicon, germanium, doped silicon, doped germanium, and/or polysilicon. In some example embodiments, the etching target layer 200 may include silicon oxide, silicon nitride, silicon carbide oxide (SiOC), silicon boron nitride (SiBN), silicon carbonitride (SiCN), and/or a combination thereof. The etching target layer 200 may include a single layer or a multi-layer. The etching target layer 200 may include a first portion, a second portion, and a third portion from a plan view.

Herein, the upper layer may refer to any one of a protective layer 310 or an under layer 320. The protective layer 310 may be formed on the etching target layer 200. The protective layer 310 may protect the etching target layer 200 in the patterning process. The protective layer 310 may include a silicon film, a silicon oxide film, a silicon nitride film, and/or a silicon oxynitride film. The protective layer 310 may be formed by a deposition process, such as plasma-enhanced chemical vapor deposition (PECVD). In an example, the protective layer 310 may include a multilayer. For example, although not shown, the protective layer 310 may include a first protective layer and a second protective layer. The first protective layer may be provided between the etching target layer 200 and the second protective layer. The first protective layer may attach the second protective layer to the etching target layer 200. In one example, the first protective layer may function as an anti-glare film. The first protective layer may include a material that is different from the etching target layer 200 and the second protective layer. The first protective layer may include, for example, an organic material, such as a crystalline carbon film, an amorphous carbon film, or a polymer. In some example embodiments, the first protective layer may include silicon oxynitride. The second protective layer may be formed on the first protective layer. When a rework process is performed after an exposure process to be described below, the second protective layer may protect the etching target layer 200 during the rework process. The second protective layer may include a silicon-containing film, such as, but not limited to, silicon oxide, silicon nitride, and/or a combination thereof. In some example embodiments, the protective layer 310 may include a single layer.

The under layer 320 may be formed on the protective layer 310. The under layer 320 may include an organic material, such as a polymer. The under layer 320 may attach the resist pattern 500 to the etching target layer 200. The under layer 320 may support the resist pattern 500.

The resist pattern 500 may be formed on the etching target layer 200 to cover a portion of a top surface of the under layer 320. The resist pattern 500 may expose another portion of the top surface of the under layer 320. From a plan view, the resist pattern 500 may overlap the first portion of the etching target layer 200 and may be spaced apart from the second portion and the third portion of the etching target layer 200.

Herein, the resist pattern 500 may include a resist pattern. The resist pattern 500 may include metal oxide. For example, the resist pattern 500 may include tin oxide, zirconium oxide, aluminum oxide, hafnium oxide, zinc oxide, titanium oxide, and/or a combination thereof.

Because the resist pattern 500 contains metal oxide, the resist pattern 500 may be formed with a relatively small thickness T1. For example, the thickness T1 of the resist pattern 500 may be about 10 nm to about 100 nm. Because the thickness T1 of the resist pattern 500 is 100 nm or less, the productivity and/or efficiency of the patterning process may be improved.

Because the resist pattern 500 includes metal oxide, the aspect ratio of the resist pattern 500 may be relatively small. The aspect ratio of the resist pattern 500 may include a ratio of the thickness T1 to the width of the resist pattern 500. The aspect ratio of the resist pattern 500 may be about 0.5 to about 3. As the resist pattern 500 has a relatively small aspect ratio (e.g., less than or equal to 3), the resist pattern 500 may have structural stability in the process of forming a pattern.

Forming the resist pattern 500 may include forming a resist layer on the protective layer 310 and patterning the resist layer. The resist layer may be formed by a deposition process, such as chemical vapor deposition (CVD). In some example embodiments, the resist layer may be formed by a coating process, such as spin coating. Patterning the resist layer may include performing an exposure process and a development process on the resist layer. In the exposure process, a krypton fluoride (KrF) light source, an argon fluoride (ArF) light source, or an extreme-ultraviolet (EUV) light source may be used. The EUV light may refer to ultraviolet light having a wavelength of about 12 nm to about 14 nm (e.g., a wavelength of about 13.0 nm to about 13.9 nm or a wavelength of about 13.4 nm to about 13.6 nm. Because the resist pattern 500 contains metal oxide, pattern masking performance may be improved. Accordingly, the productivity and/or the distribution of the patterning process may be further improved.

The resist pattern 500 may be one of a plurality of resist patterns 500. The resist patterns 500 may be spaced apart from each other in a first direction D1. The resist patterns 500 may have a first pitch P1. As shown in FIG. 1A, each of the resist patterns 500 may extend in a second direction D2. For example, long axes of the resist patterns 500 may be parallel to the second direction D2. The first direction D1 may be parallel to the top surface of the substrate 100. The second direction D2 may be parallel to the top surface of the substrate 100 and may intersect the first direction D1. For example, the second direction D2 may be substantially perpendicular to the first direction D1. A third direction D3 may intersect the first direction D1 and the second direction D2. For example, the third direction D3 may be substantially perpendicular to the top surface of the substrate 100. The third direction D3 may include a vertical direction. As an example, each of the resist patterns 500 may have a bar shape from a plan view. However, the bar shape of the resist patterns 500 from a plan view is an example and may be variously modified without being limited as shown in FIG. 1A. In one example, the resist patterns 500 may have a circular shape from a plan view.

FIG. 1C is a diagram illustrating a formation process of a spacer film 610, according to an example embodiment, corresponding to a cross-sectional view taken along line I-I′ in FIG. 1A.

Referring to FIG. 1C, the spacer film 610 may be formed on the substrate 100. The spacer film 610 may be formed on sidewalls and top surfaces of the resist patterns 500. The spacer film 610 may extend onto the etching target layer 200 to cover the top surface of the protective layer 310. The spacer film 610 may include oxide. The spacer film 610 may include, for example, silicon oxide, silicon carbide, silicon nitride, and/or a combination thereof. The spacer film 610 may be formed by a deposition process, such as an atomic layer deposition (ALD) process. Because the spacer film 610 is formed by an ALD process, the spacer film 610 may have a relatively small thickness. By adjusting the process conditions of the ALD process, the thickness of the spacer film 610 may be variously adjusted to satisfy a desired range. For example, the thickness of the spacer film 610 may be less than the thickness T1 of the resist patterns 500.

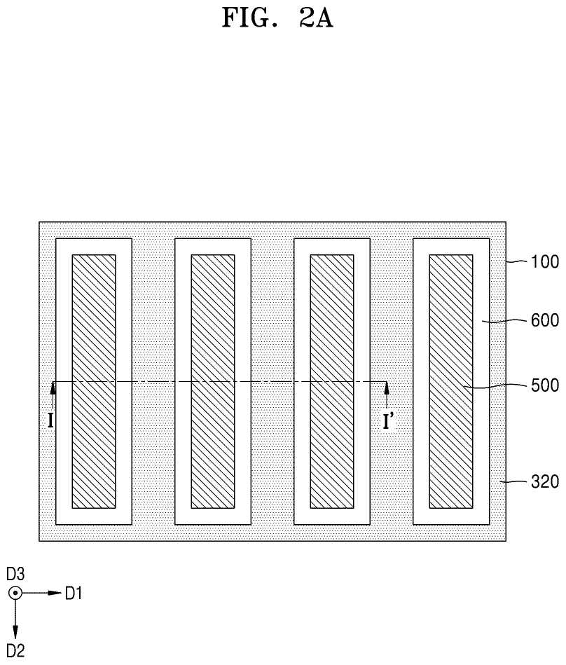

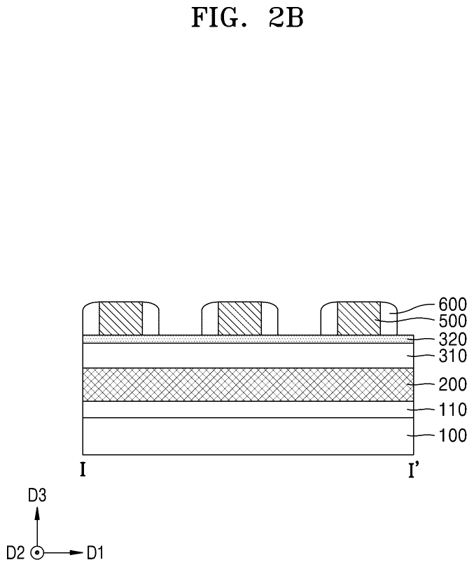

Referring to FIGS. 2A and 2B, portions of the spacer film 610 may be removed to form spacer patterns 600. For example, the removing of the portions of the spacer film 610 may be performed by an etching process. The etching process may be performed to expose the top surface of the under layer 320 and the top surfaces of the resist patterns 500. The spacer patterns 600 may cover sidewalls of the resist patterns 500.

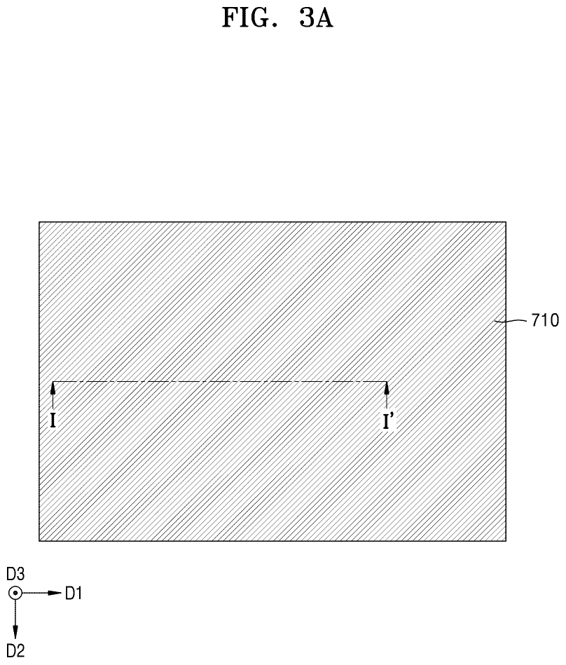

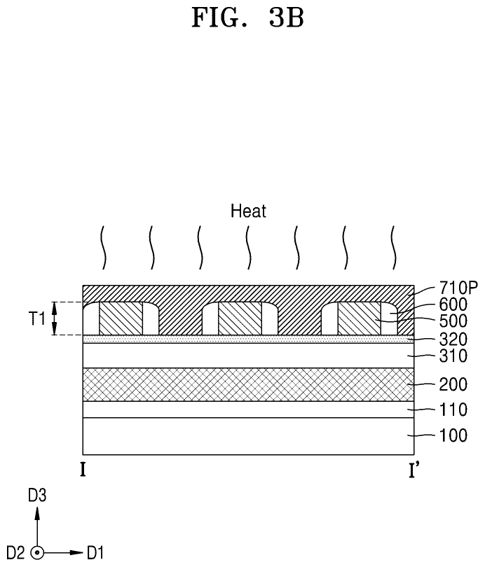

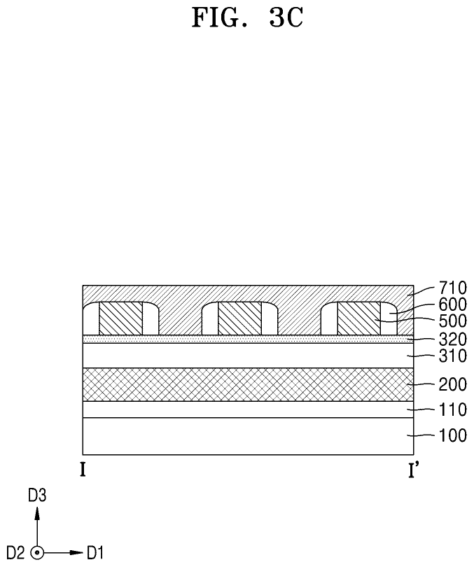

Referring to FIGS. 3A and 3B, a precursor may be coated on the resist patterns 500 and the spacer patterns 600 to form a preliminary metal oxide layer 710P. The preliminary metal oxide layer 710P may cover the outer walls of the spacer patterns 600 and the top surfaces of the resist patterns 500.

The precursor may include a metal precursor. The precursor may include metal oxide and a solvent. The metal oxide may include tin oxide (SnOx), zinc oxide (ZnOx), titanium oxide (TiOx), zirconium oxide (ZrOx), hafnium oxide (HfOx), and/or a combination thereof, where x is a positive rational number. The metal oxide may be provided and dispersed in the solvent. The precursor may include a metal-ligand compound, and the metal-ligand compound may include a metal ion and a ligand. The precursor may be in any one of a solution state, a sol state, or a gel state. For example, when the precursor is in a sol state and a gel state, the precursor may be the same suspension or colloidal solution. When the precursor is in a sol state, the precursor may include particles of about 1 nm to about 1000 nm. The particles may include the metal oxide described above. The particles may be uniformly dispersed in the solvent without precipitation. When the precursor is in a solution state, the metal oxide may be mixed with a solvent to form one phase and the precursor may be transparent. The coating with the precursor may be performed by a coating process, such as spin coating.

According to the present example embodiment, because the preliminary metal oxide layer 710P is formed by the coating process using the precursor, the preliminary metal oxide layer 710P easily fills the gap region between the resist patterns 500, thereby improving the productivity of the patterning process. In addition, because the resist patterns 500 have a relatively small thickness T1 and the preliminary metal oxide layer 710P is formed by the coating process using the precursor, the preliminary metal oxide layer 710P may satisfactorily fill the gap region between the resist patterns 500. Accordingly, formation of voids in the preliminary metal oxide layer 710P may be reduced or prevented. In some example embodiments, the gap region may be provided between the outer walls of the spacer patterns 600.

FIG. 3C is a diagram illustrating the formation of the metal oxide layer 710 according to an example embodiment, corresponding to a cross-sectional view taken along line I-I′ of FIG. 3A.

Referring to FIGS. 3B and 3C in turn, the preliminary metal oxide layer 710P may be solidified to form the metal oxide layer 710. The solidifying of the preliminary metal oxide layer 710P may be performed by a first heat treatment process. The first heat treatment process may be performed at a temperature of, for example, about 50 °C to about 200 °C. The solvent in the preliminary metal oxide layer 710P may be removed by the first heat treatment process. Accordingly, the preliminary metal oxide layer 710P may be solidified to form the metal oxide layer 710. Because the first heat treatment process is performed at a temperature of 200 °C or less, the productivity and/or efficiency of the patterning process may be improved. Because the first heat treatment process is performed at a temperature of 50 °C or greater, the preliminary metal oxide layer 710P may be satisfactorily solidified. The first heat treatment process may correspond to or referred to as a bake process of the preliminary metal oxide layer 710P.

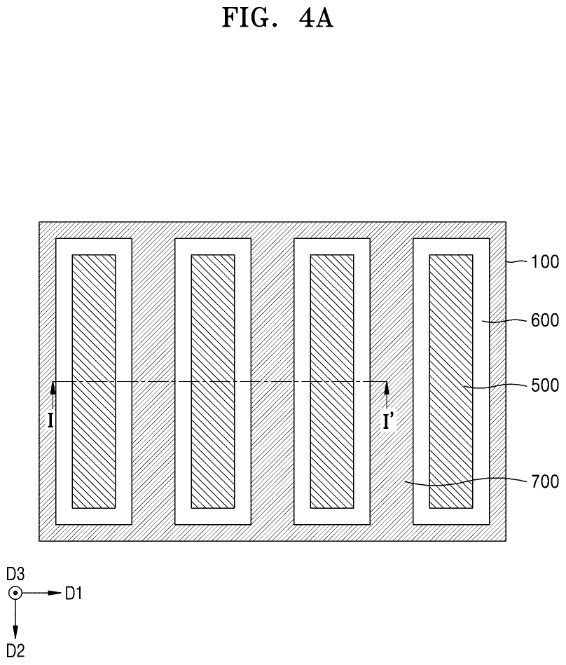

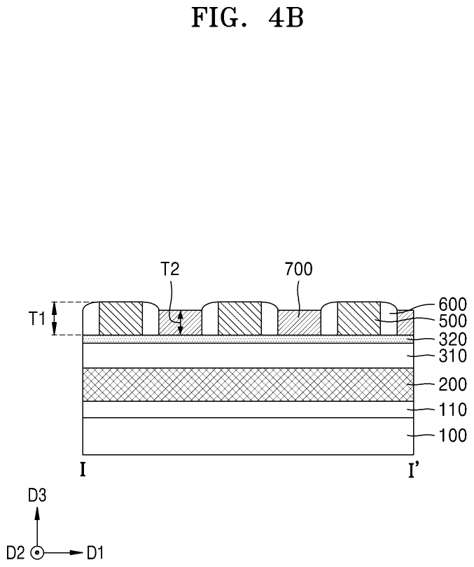

Referring to FIGS. 4A and 4B, a portion of the metal oxide layer 710 may be removed to form a metal oxide pattern 700. The portion of the metal oxide layer 710 may include a portion on top surfaces of the resist patterns 500 and a portion on top surfaces of the spacer patterns 600. Accordingly, the resist patterns 500 and the spacer patterns 600 may be exposed. As an example, the removing of the portion of the metal oxide layer 710 may be performed by an etch-back process. The etch-back process may include a physical etching process or a dry etching process. As another example, the removing of the portion of the metal oxide layer 710 may be performed by a chemical mechanical polishing (CMP) process. Buffers may be used in the CMP process.

The metal oxide pattern 700 may have a relatively high oxygen content because the forming of the metal oxide pattern 700 includes coating with the precursor in a solution, sol, or gel state described with reference to FIG. 3B. An oxygen content in the metal oxide pattern 700 may be greater than that in the resist patterns 500. A metal content in the metal oxide pattern 700 may be less than that in the resist pattern 500. A second metal in the metal oxide pattern 700 may be the same as or different from a first metal in the resist patterns 500.

A thickness T2 of the metal oxide pattern 700 may be less than the thickness T1 of the resist patterns 500. The thickness T2 of the metal oxide pattern 700 may be between about 10 nm and about 100 nm. The top surface of the metal oxide pattern 700 may be provided at a lower level than the top surfaces of the resist patterns 500. The level of a certain component may refer to a vertical level measured in the vertical direction. The vertical direction may be parallel to the third direction D3.

The metal oxide pattern 700 may be laterally spaced apart from the resist patterns 500. For example, the spacer patterns 600 may be arranged between the metal oxide pattern 700 and the resist patterns 500. Being laterally spaced apart from one another may refer to being horizontally spaced apart from one another. Being “horizontal” may refer to being parallel to the top surface of the substrate 100. The metal oxide pattern 700 may be disposed on the same plane as the resist patterns 500. For example, a bottom surface of the metal oxide pattern 700 may be provided at the same or substantially similar level as bottom surfaces of the resist patterns 500. The bottom surfaces of the resist patterns 500 may be opposite to the top surfaces of the resist patterns 500. The bottom surfaces of the resist patterns 500 may face the substrate 100. In this specification, the metal oxide pattern 700 may be referred to as a second metal oxide pattern 700. The metal oxide pattern 700 may overlap the second portion of the etching target layer 200 from a plan view.

Referring to FIGS. 5A to 5D, a pattern block mask 900 may be formed on the resist patterns 500, the spacer patterns 600, and the metal oxide pattern 700. The pattern block mask 900 may cover ends 502 of the resist patterns 500 and ends 602 of the spacer patterns 600. In one example, the pattern block mask 900 may include a polymer. The polymer may include polyimide, aromatic polymer, acrylate-based polymer, polyamide, hydroxy styrene polymer, and/or polymer including silicone. As another example, the pattern block mask 900 may include metal or metal oxide.

As shown in FIG. 5A, the metal oxide pattern 700 may include a first portion 701 and second portions 702. The first portion 701 of the metal oxide pattern 700 may be provided between the resist patterns 500. The first portion 701 of the metal oxide pattern 700 may have a bar shape from a plan view. The first portion 701 of the metal oxide pattern 700 may extend in a direction parallel to the second direction D2. The first portion 701 of the metal oxide pattern 700 may be provided between the second portions 702. The second portions 702 of the metal oxide pattern 700 may be provided outside the first portion 701 and connected with the first portion 701. The second portions 702 of the metal oxide pattern 700 may be provided between the ends 602 of the spacer patterns 600 and outside the ends 602 of the spacer patterns 600. The pattern block mask 900 may cover the second portions 702 of the metal oxide pattern 700.

The pattern block mask 900 may have a mask opening 990. The mask opening 990 may expose the first portions 501 of the resist patterns 500, the first portions 601 of the spacer patterns 600, and the first portions 701 of the metal oxide pattern 700. The first portions 501 of the resist patterns 500 may be provided between the ends 502 of the resist patterns 500. The first portions 601 of the spacer patterns 600 may be provided between the ends 602 of the spacer patterns 600. The first portions 601 of the spacer patterns 600 may be provided between the first portions 501 of the resist patterns 500 and the first portion 701 of the metal oxide pattern 700.

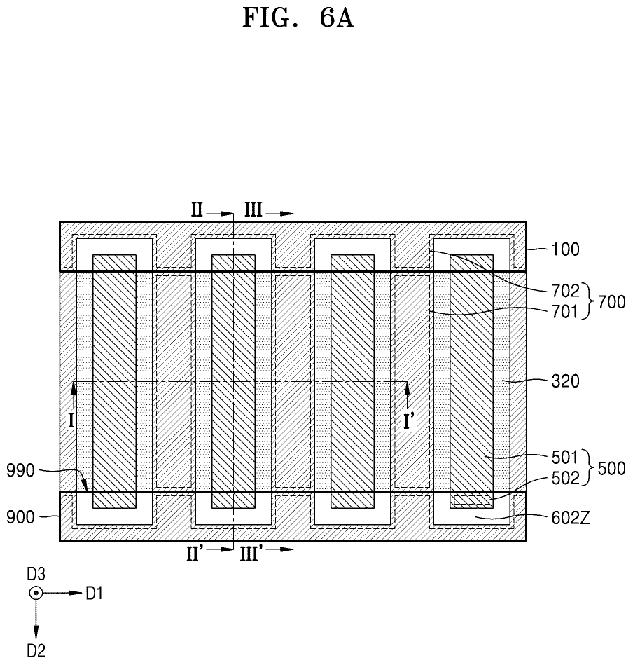

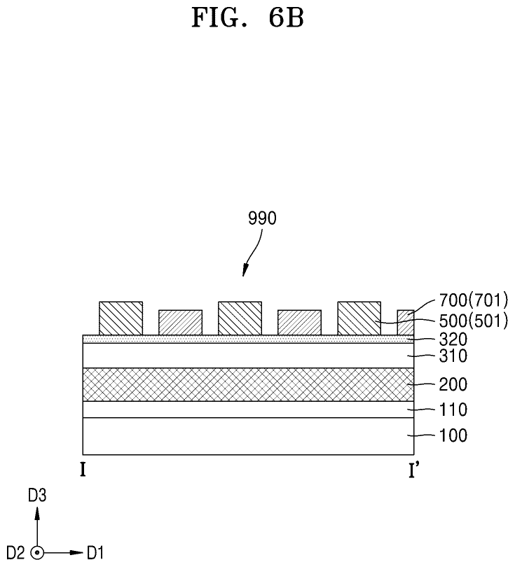

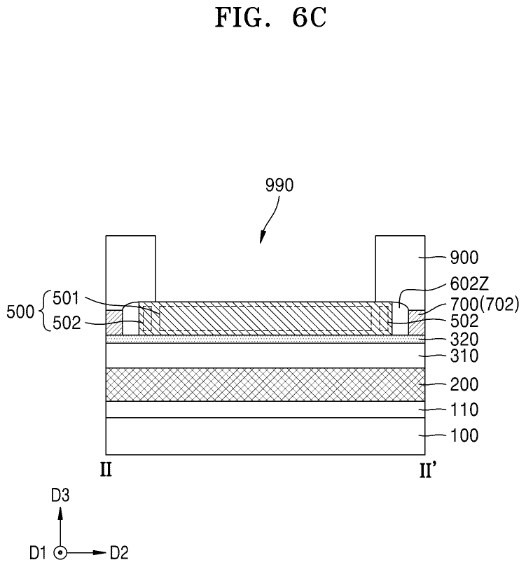

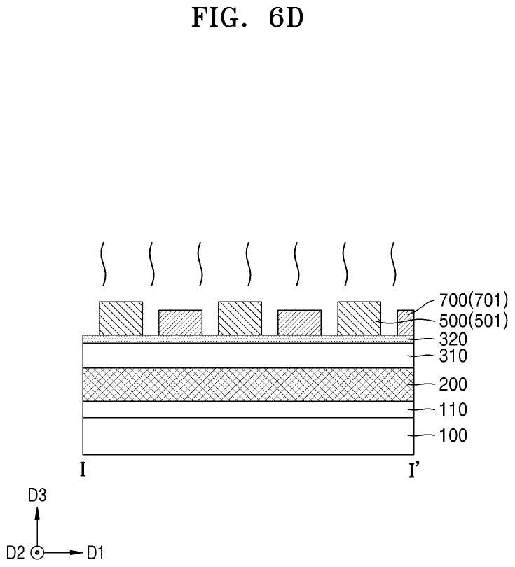

Referring to FIGS. 6A to 6C, as the spacer patterns 600 exposed to the pattern block mask 900 are removed, the top surface of the under layer 320 may be exposed. The removing of the spacer patterns 600 may be performed by an etch process. For example, the etching process may be performed by a dry etching process, a wet etching process, or a combination thereof. A halogen gas, such as hydrogen fluoride, may be used in the dry etching process.

However, as shown in FIGS. 6A and 6C, the ends 602 of the spacer patterns 600 may be covered by the pattern block mask 900 during the etching process, thus the ends 602 of the spacer patterns 600 may not be exposed to the etching process. The ends 602 of the spacer patterns 600 may form the remaining spacer patterns 602Z.

The cross-sectional view taken along line III-III′ of FIG. 6A may be the same as or substantially the similar to that of FIG. 5D.

FIG. 6D is a diagram illustrating a second heat treatment process according to an example embodiment, corresponding to a cross-sectional view taken along line I-I′ of FIG. 6A.

Referring to FIG. 6D, the second heat treatment process may be further performed on the metal oxide pattern 700. The second heat treatment process may be performed at a greater temperature than the first heat treatment process of FIG. 3C. The second heat treatment process may be performed using a hydrogen-containing gas. The hydrogen-containing gas may include a hydrogen (H₂) gas, a hydrogen nitride (H₂N₂) gas, a mixed gas of hydrogen gas and inert gas, and/or a mixed gas of hydrogen gas and nitrogen gas. The inert gas may include an argon gas.

For example, the second heat treatment process may be performed at a temperature of, for example, about 250 °C to about 700 °C. Moisture in the metal oxide pattern 700 may be removed by the second heat treatment process. For example, an oxygen content in the metal oxide pattern 700 after the second heat treatment process may be less than an oxygen content in the metal oxide pattern 700 before the second heat treatment process. Accordingly, the modulus (alternatively, referred to as modulus of elasticity, elastic modulus, or Young's modulus) of the metal oxide pattern 700 may be increased. The second heat treatment process may be performed at a temperature of 250 °C or greater to sufficiently remove moisture in the metal oxide pattern 700, thereby sufficiently improving the modulus of the metal oxide pattern 700. The second heat treatment process may be performed at a temperature of 700 °C or less, thereby improving the productivity of the patterning process.

An oxygen content in the metal oxide pattern 700 after the second heat treatment process may be greater than that in the resist patterns 500. A metal content in the metal oxide pattern 700 after the second heat treatment process may be less than that in the resist patterns 500.

In some example embodiments, the second heat treatment process may not be performed.

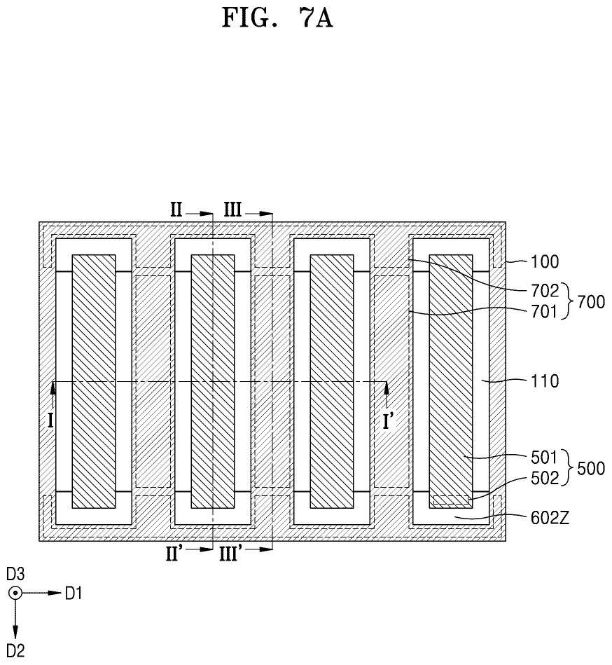

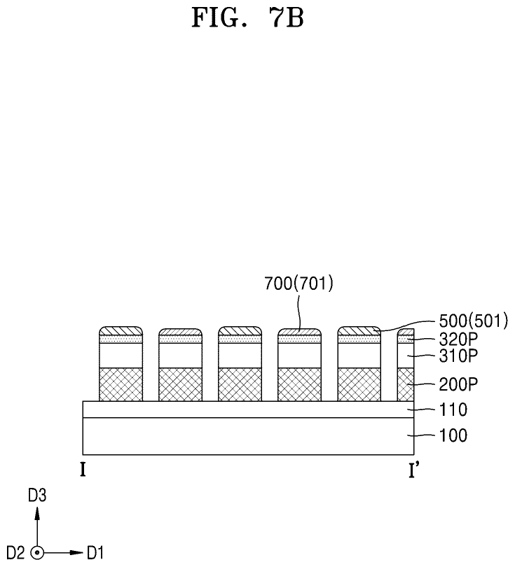

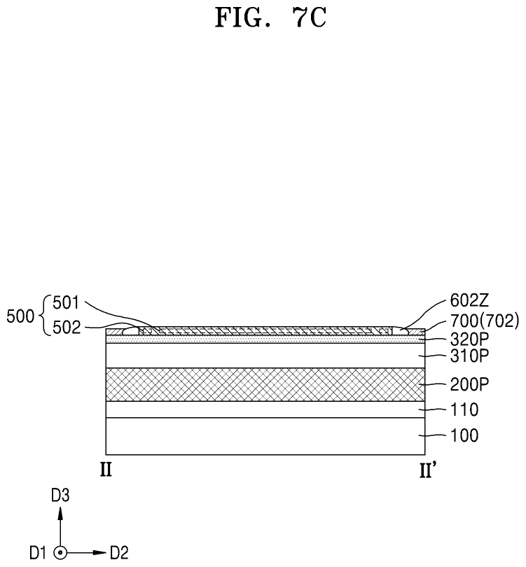

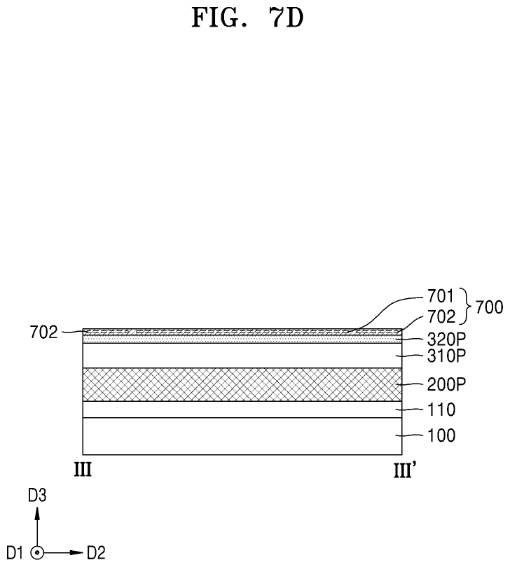

Referring to FIGS. 7A to 7D together with FIGS. 6A to 6C, the etching process using the resist patterns 500 and the metal oxide pattern 700 as an etching mask may be performed to etch the under layer 320, the protective layer 310, and the etching target layer 200. The etching process may be performed on the under layer 320, the protective layer 310, and the etching target layer 200 exposed in the mask opening 990. The etching process may include a single etching process or multiple etching processes.

A portion of the under layer 320 exposed to the resist patterns 500 and the metal oxide pattern 700 may be removed by the etching process to form an under pattern 320P. The portion of the under layer 320 may be exposed through the mask opening 990. The under pattern 320P may expose a portion of the protective layer 310. The exposed portion of the protective layer 310 may be removed by the etching process to form a protective pattern 310P. The protective pattern 310P may be disposed on the first portion and the second portion of the etching target layer 200 and may expose the top surface of the third portion of the etching target layer 200.

The third portion of the etching target layer 200 may be removed by the etching process to form a target pattern 200P. For example, after the etching process, the first and second portions of the etching target layer 200 may form the target pattern 200P. The target pattern 200P may expose the lower layer 110. In some example embodiments, when the lower layer 110 is omitted, the target pattern 200P may expose the substrate 100.

In the etching process of the etching target layer 200, as the resist patterns 500 and the metal oxide pattern 700 may be recessed to remove the upper portions of the resist patterns 500 and the upper portion of the metal oxide pattern 700. However, the lower portions of the resist patterns 500 and the lower portion of the metal oxide pattern 700 may not be removed. Because the resist pattern 500 has a thickness T1 of 10 nm or more as described with reference to FIG. 1B, the resist patterns 500 may function well as an etching mask. For example, while the etching target layer 200 is etched, the resist patterns 500 may remain at a sufficient thickness. Similarly, as described with reference to FIG. 4B, because the metal oxide pattern 700 has the thickness T2 of 10 nm or more, the metal oxide pattern 70 may function well as an etching mask. For example, while the etching target layer 200 is etched, the metal oxide pattern 700 may remain at a sufficient thickness.

As another example, in the etching process of the etching target layer 200, the resist patterns 500 and the metal oxide pattern 700 may be removed to expose the top surface of the under pattern 320P. However, at least a portion of the protective pattern 310P may remain unremoved.

According to the present example embodiment, because the etching target layer 200 is etched using the resist patterns 500 and the metal oxide pattern 700 as an etching mask, a hard mask may be omitted between the etching target layer 200 and the resist patterns 500. For example, the etching selectivity of the resist patterns 500 and the etching target layer 200 and the etching selectivity of the metal oxide pattern 700 and the etching target layer 200 may be adjusted to omit the hard mask. Accordingly, the process of forming a pattern may be simplified, and the productivity of the process of forming a pattern may be improved.

The pattern block mask 900 may be removed. Accordingly, the ends 502 of the resist patterns 500, the remaining spacer patterns 600Z, and the second portions 702 of the metal oxide pattern 700 may be exposed. The pattern block mask 900 may be removed during any one of an etching process of the under layer 320, an etching process of the protective layer 310, or an etching process of the etching target layer 200, or may be removed by a separate process.

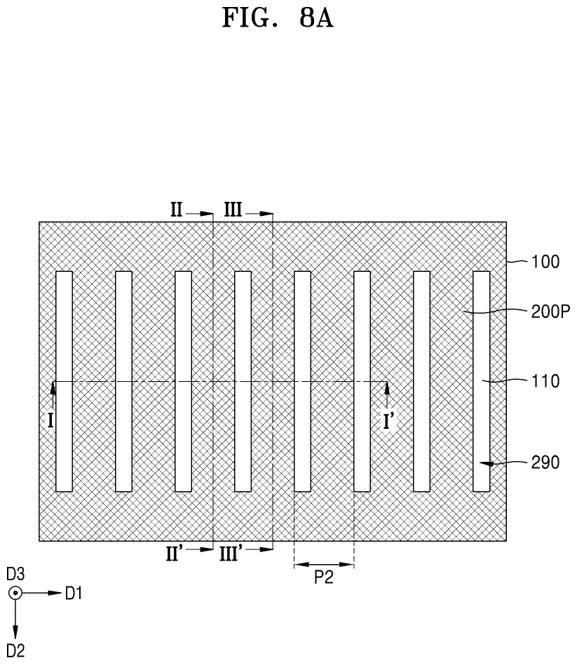

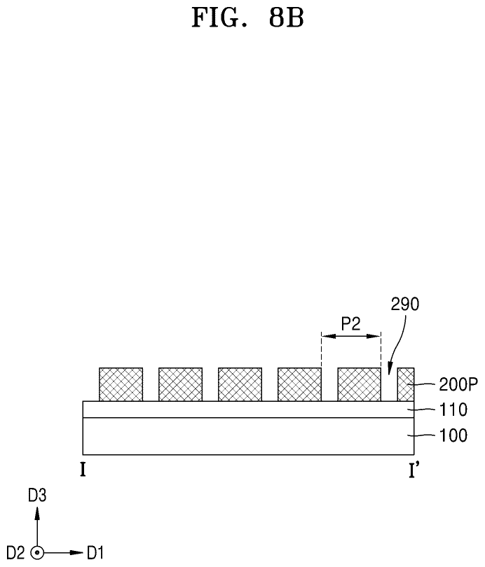

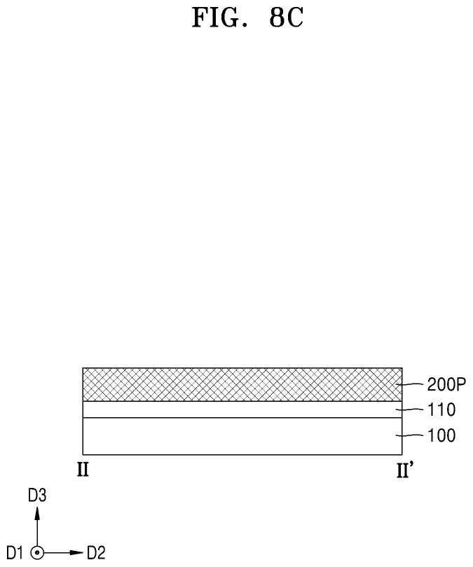

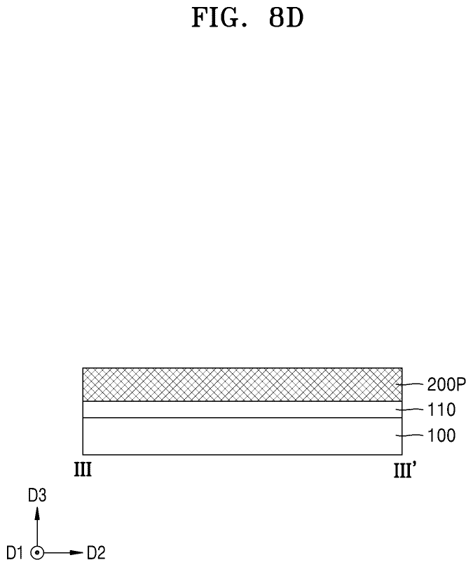

Referring to FIGS. 8A to 8D, the resist patterns 500, the metal oxide pattern 700, the under pattern 320P, and the protective pattern 310P may be removed to expose the top surface of the target pattern 200P.

According to the present example embodiment, the etching target layer 200 may be etched using the resist patterns 500 and the metal oxide pattern 700 as an etch mask. Accordingly, the target pattern 200P may be formed at a position corresponding to the resist patterns 500 and the metal oxide pattern 700. The target pattern 200P may have openings 290 passing therethrough. The openings 290 may expose the lower layer 110. The openings 290 may be formed at positions corresponding to the first portions 601 of the spacer patterns 600 exposed in the mask opening 990 of FIGS. 5A and 5B. The openings 290 may be formed with the same pitch/width/length as or similar pitch/width/length to the first portions 601 of the spacer patterns 600 of FIGS. 5A and 5B.

According to the present example embodiment, even though the resist patterns 500 are formed with the relatively large first pitch P1, the openings 290 may be formed with a relatively fine second pitch P2 using the resist patterns 500 and the metal oxide pattern 700 as an etching mask. For example, the second pitch P2 may be less than the first pitch P1 of the resist patterns 500 of FIG. 1B. For example, the second pitch P2 may be half of the first pitch P1 of the resist patterns 500 of FIG. 1B. As an example, the second pitch P2 may be about 45% to about 55% of the first pitch P1 of the resist patterns 500 of FIG. 1B. For example, the second pitch P2 may be between about 10 nm and about 80 nm. Accordingly, the dose of the exposure process for forming the resist patterns 500 may be reduced. Thus, the efficiency and/or productivity of the process of forming a pattern may be further improved.

The target pattern 200P may include a component of the semiconductor device. For example, the target pattern 200P may include a conductive pattern in the semiconductor device. The conductive pattern may function as an electrode or wiring. For example, the conductive pattern may function as a gate electrode, a word line, or a bit line, but functions of the conductive pattern are not limited thereto.

The target pattern 200P may further include metal. The metal may include at least one of the first metal included in the metal oxide of the resist patterns 500 or the second metal included in the metal oxide pattern 700. That is, a portion of the first metal included in the resist patterns 500 and/or the second metal included in the metal oxide pattern 700 may remain in the target pattern 200P. When the target pattern 200P further includes the first metal, the concentration of the first metal in the target pattern 200 P may be about 1E11/cm³ or less. When the target pattern 200P further includes the second metal, the concentration of the second metal in the target pattern 200P may be about 1E11/cm³ or less. In one example, the first metal may include, but is not limited to, tin, zinc, or a combination thereof. The second metal may include, but is not limited to, tin, zinc, or a combination thereof.

In another example, the target pattern 200P may include a semiconductor pattern or an insulating pattern in the semiconductor device.

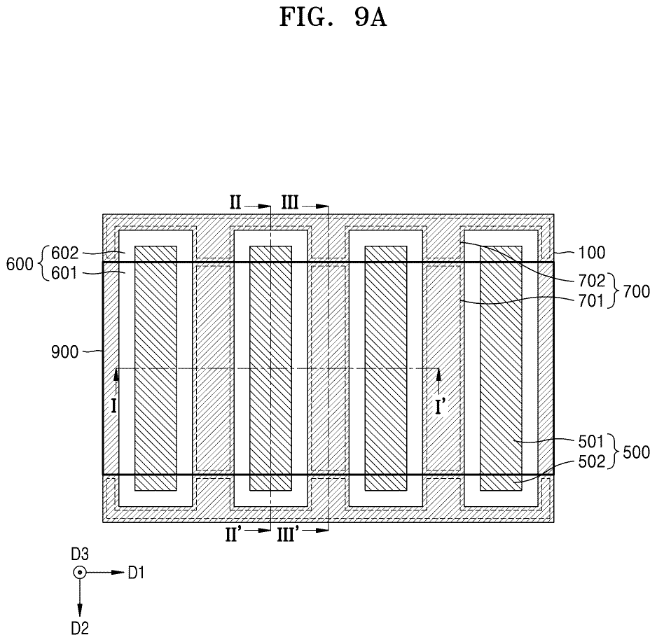

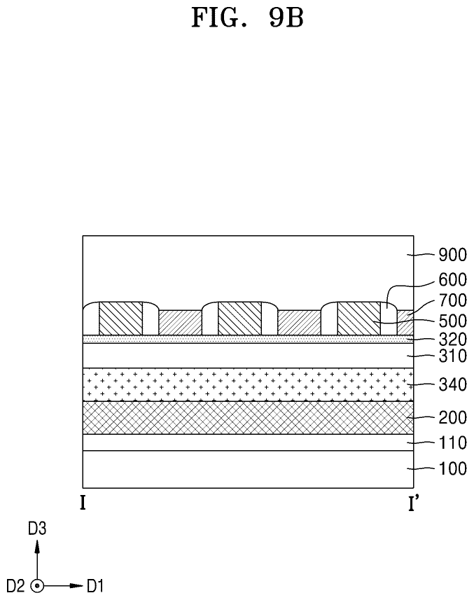

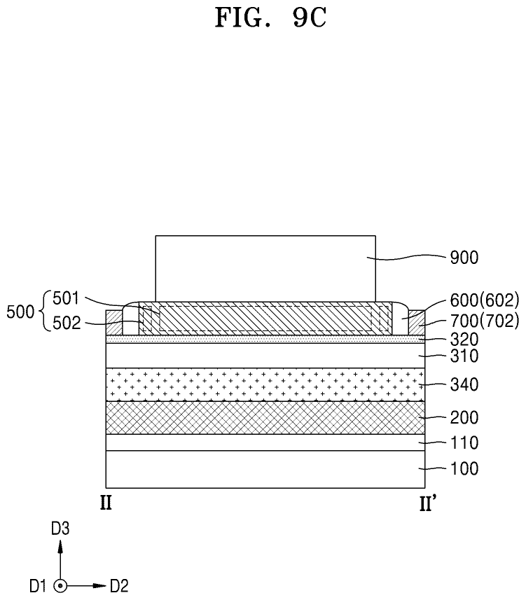

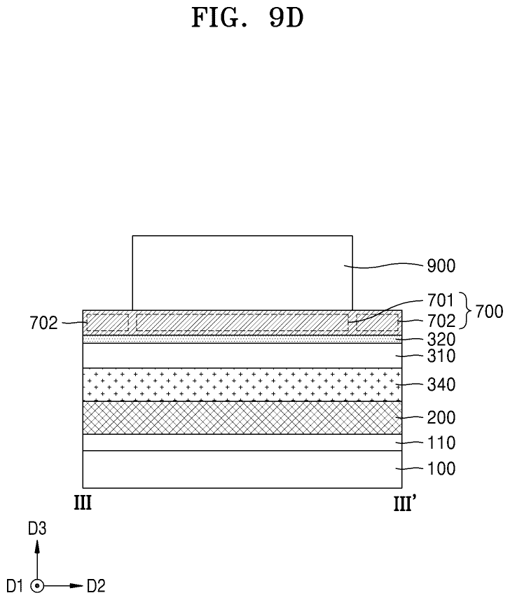

FIGS. 9A to 13D are diagrams illustrating a method of forming a pattern, according to an example embodiment. Hereinafter, descriptions that are the same as or substantially similar to those given above may be omitted.

Referring to FIGS. 9A to 9D, the substrate 100, on which the lower layer 110, the etching target layer 200, the protective layer 310, the under layer 320, and the resist patterns 500 are stacked, may be prepared. However, an etching stop layer 340 may be further formed between the etching target layer 200 and the protective layer 310. The etching stop layer 340 may include, for example, silicon oxide, silicon nitride oxide, and/or silicon carbide oxide.

The resist patterns 500, the spacer patterns 600, and the metal oxide pattern 700 may be formed by the methods described above with reference to FIGS. 1A to 4B. The forming of the metal oxide pattern 700 may include performing a sol-gel method. For example, the precursor in a solution, sol, or gel state may be coated on resist patterns 500 and the spacer patterns 600 to form the preliminary metal oxide layer 710P as shown in FIG. 3B. The preliminary metal oxide layer 710P may be solidified by the first heat treatment process as shown in FIG. 3C to form the metal oxide layer 710. As shown in FIG. 4B, the metal oxide layer 710 may be recessed to form the metal oxide pattern 700.

The pattern block mask 900 may be formed on the first portions 501 of the resist patterns 500, the first portions 601 of the spacer patterns 600, and the first portion 701 of the metal oxide pattern 700. The pattern block mask 900 may expose the ends 502 of the resist patterns 500, the ends 602 of the spacer patterns 600, and the second portions 702 of the metal oxide pattern 700.

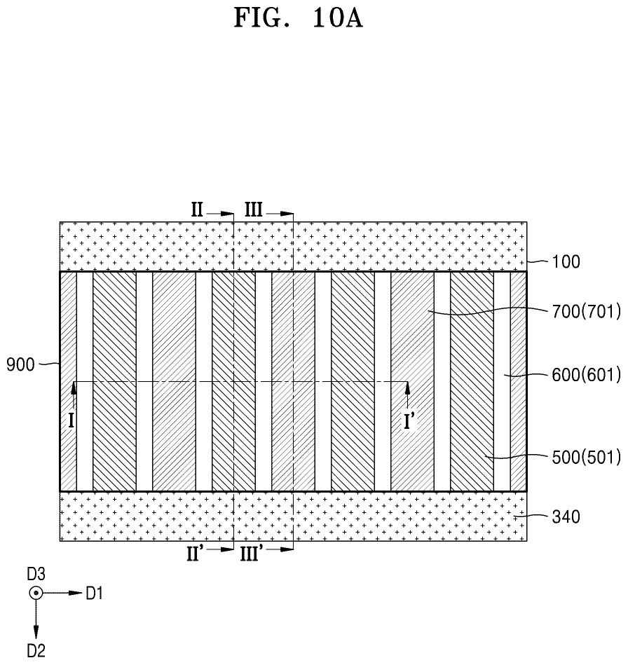

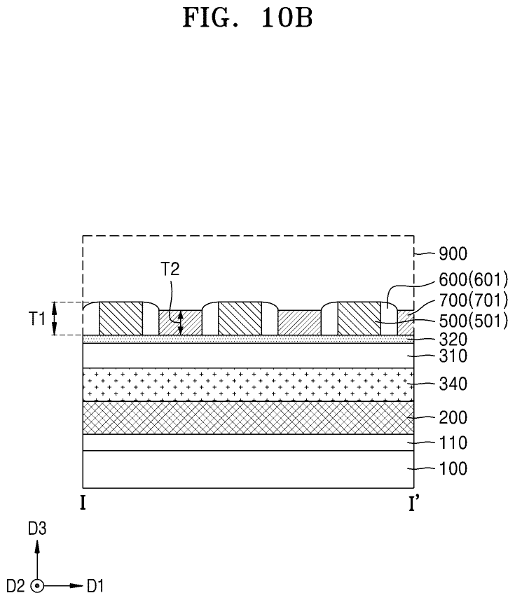

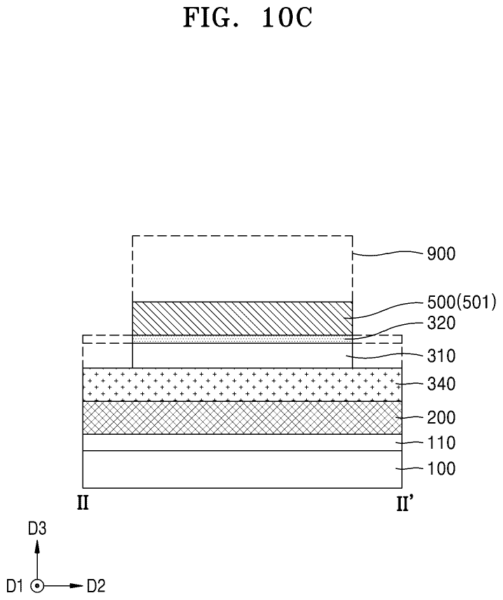

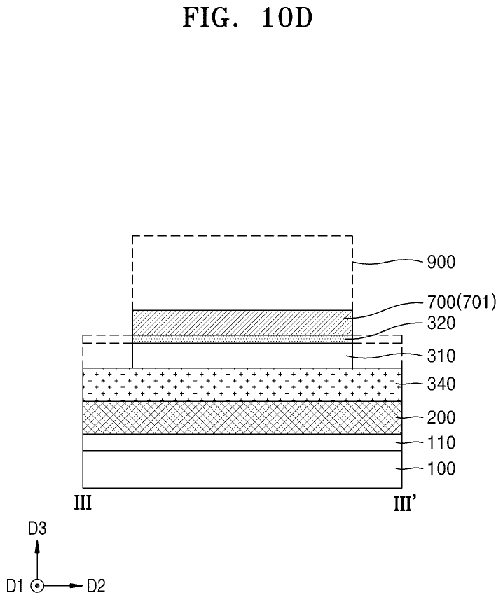

Referring to FIGS. 10A to 10D, the ends 502 of the resist patterns 500, the ends 602 of the spacer patterns 600, and the second portions 702 of the metal oxide pattern 700 exposed to the pattern block mask 900 may be removed by an etching process. Accordingly, a portion of the under layer 320 may be exposed. The exposed portion of the under layer 320 and a portion of the protective layer 310 corresponding thereto may be removed by an etching process to expose the top surface of the etching stop layer 340. Because the second portions 702 of the metal oxide pattern 700 are removed, the plurality of first portions 701 of the metal oxide pattern 700 may not be connected to each other as shown in FIG. 10A.

The pattern block mask 900 may be removed, as indicated by the dashed line, to expose the resist patterns 500, the spacer patterns 600, and the metal oxide pattern 700. The removing of the pattern block mask 900 may include, for example, performing an etch process or an ashing process.

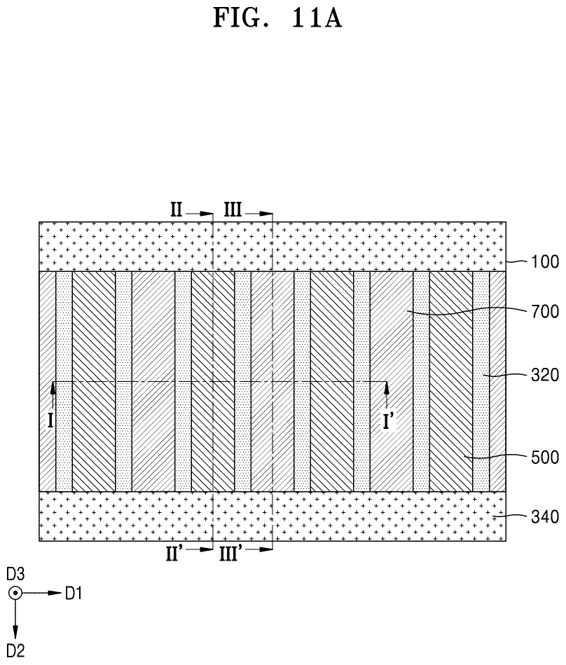

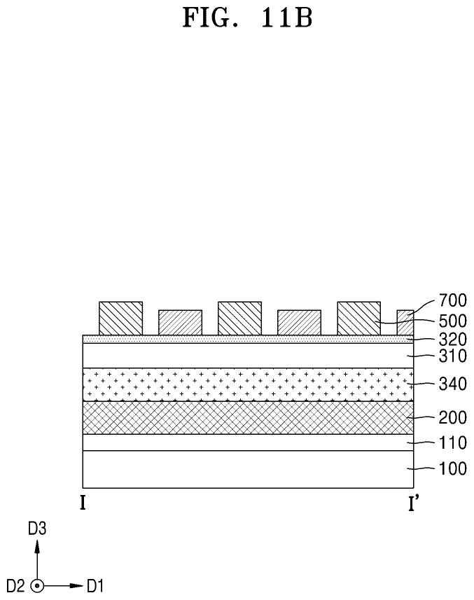

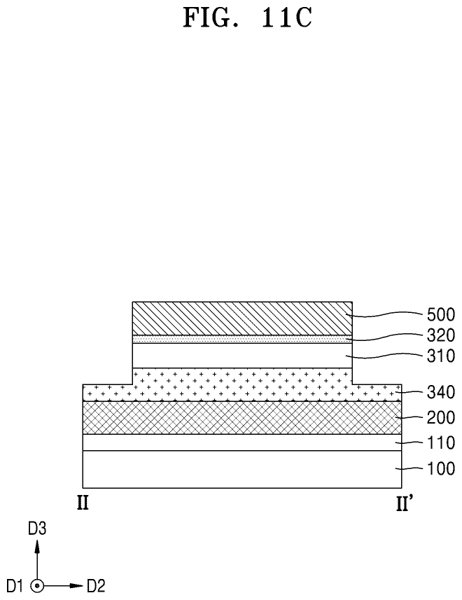

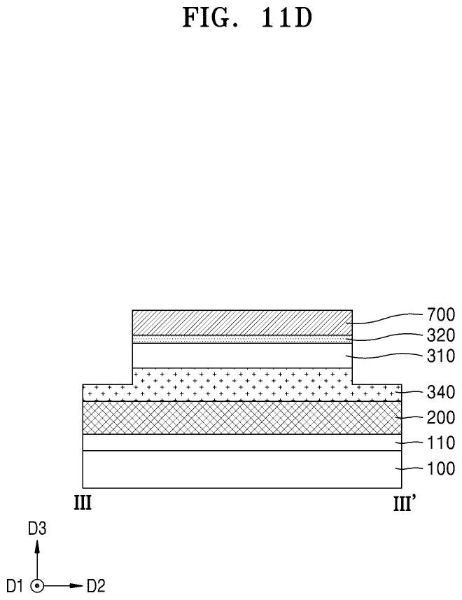

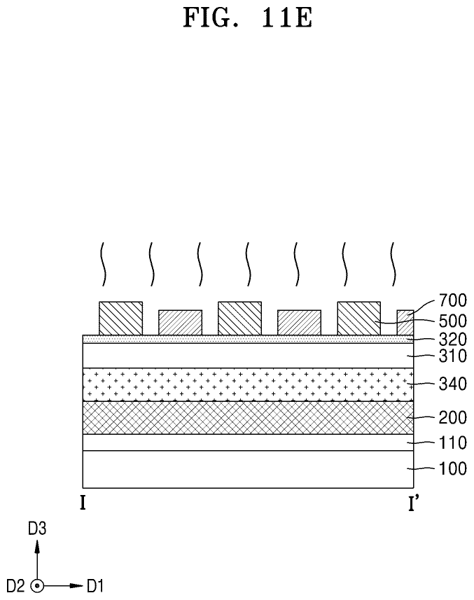

Referring to FIGS. 11A to 11D, the spacer patterns 600 may be removed by an etching process to expose the top surface of the under layer 320. In the etching process, the upper portion of the exposed etching stop layer 340 as shown in FIGS. 11C and 11D may be etched together. After the etching process is completed, the lower portion of the etching stop layer 340 may remain. In some example embodiments, after the etching process is completed, the exposed etching stop layer 340 may be removed to partially expose the top surface of the etching target layer 200.

FIG. 11E is a diagram illustrating a second heat treatment process according to an example embodiment, corresponding to a cross-sectional view taken along line I-I′ of FIG. 11A.

Referring to FIG. 11E, the second heat treatment process may be further performed on the metal oxide pattern 700. The second heat treatment process may be performed by the same method as described with reference to FIG. 6D. An oxygen content in the metal oxide pattern 700 after the second heat treatment process may be less than an oxygen content in metal oxide pattern 700 before the second heat treatment process. An oxygen content in the metal oxide pattern 700 after the second heat treatment process may be greater than that in the metal resist patterns 500.

In some example embodiments, the second heat treatment process may not be performed.

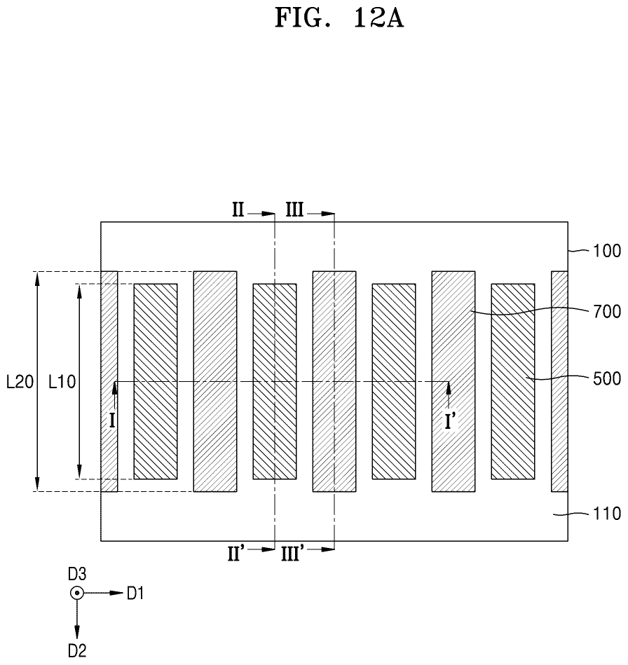

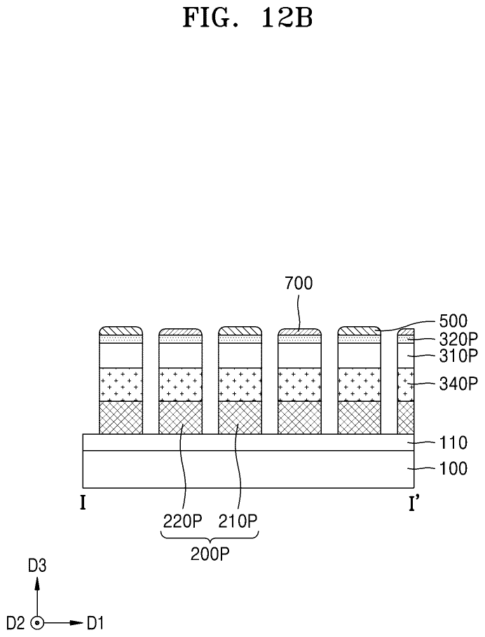

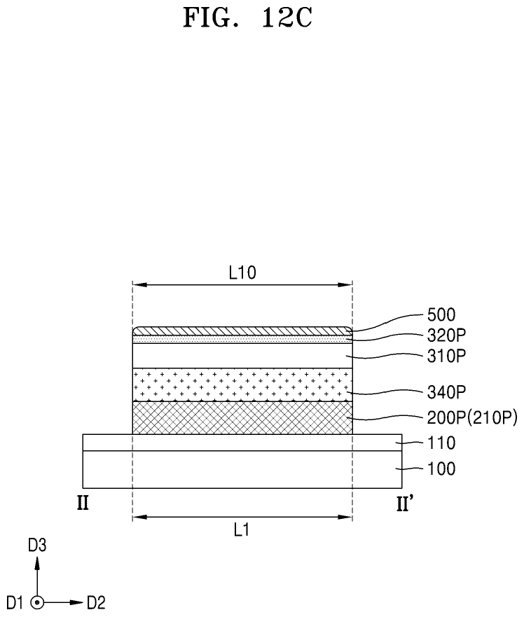

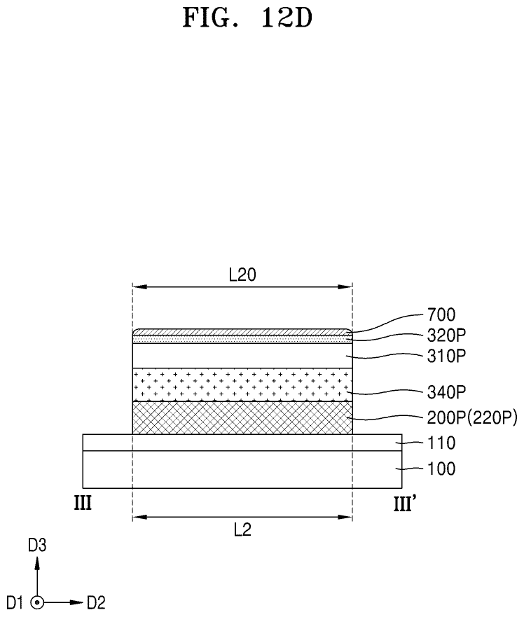

Referring to FIGS. 12A to 12D, the etching process using the resist patterns 500 and the metal oxide pattern 700 as an etching mask may be performed to etch the under layer 320, the protective layer 310, the etching stop layer 340, and the etching target layer 200. Accordingly, the under pattern 320P, the protective pattern 310P, the etching stop pattern 340P, and the target pattern 200P may be formed.

In the etching process of the etching target layer 200, the resist patterns 500 and the metal oxide pattern 700 may be partially etched. Accordingly, the resist patterns 500 and the metal oxide pattern 700 may be recessed.

Because an oxygen content in the metal oxide pattern 700 is greater than that in the resist patterns 500, the metal oxide patterns 500 may have an etching selectivity with respect to the resist patterns 500. For example, the resist patterns 500 may have a less etching resistance than the metal oxide pattern 700. Thus, the ends of the resist patterns 500 may be further recessed laterally. After the etching process is completed, a length L10 of the resist patterns 500 may be less than a length L20 of the metal oxide pattern 700. The length of a component may correspond to a length in the second direction D2.

The target pattern 200P may include a first target pattern 210P and a second target pattern 220P. The first target patterns 210P may overlap the resist patterns 500 from a plan view. The first target patterns 210P may not be exposed to the resist patterns 500 by the etching process. The first target patterns 210P may include a first portion of the etching target layer 200. For example, the first target patterns 210P may be formed from the first portion of the etching target layer 200. The second target pattern 220P may overlap the metal oxide pattern 700 from a plan view. The second target pattern 220P may not be exposed to the metal oxide pattern 700 by the etching process. The second target pattern 220P may include a second portion of the etching target layer 200. For example, the second target pattern 220P may be formed from the second portion of the etching target layer 200.

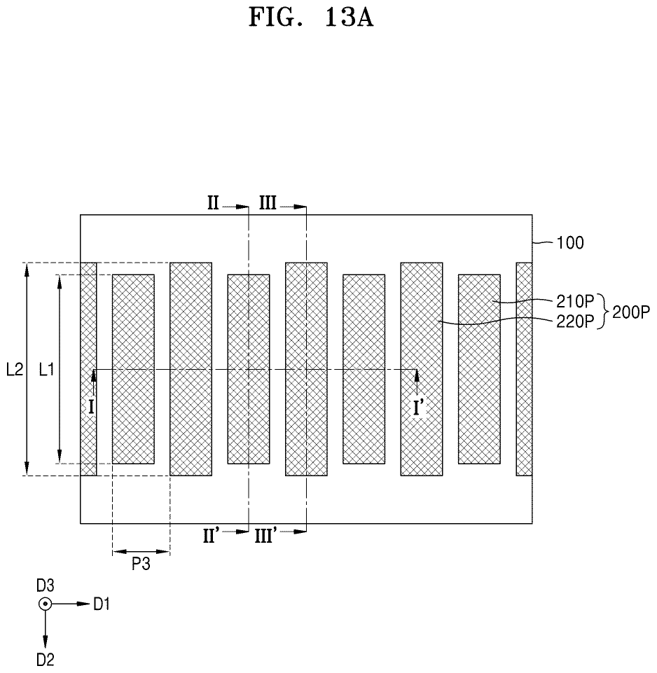

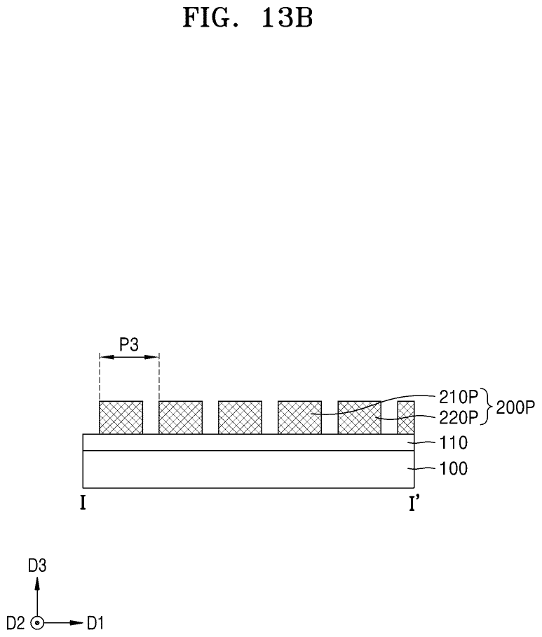

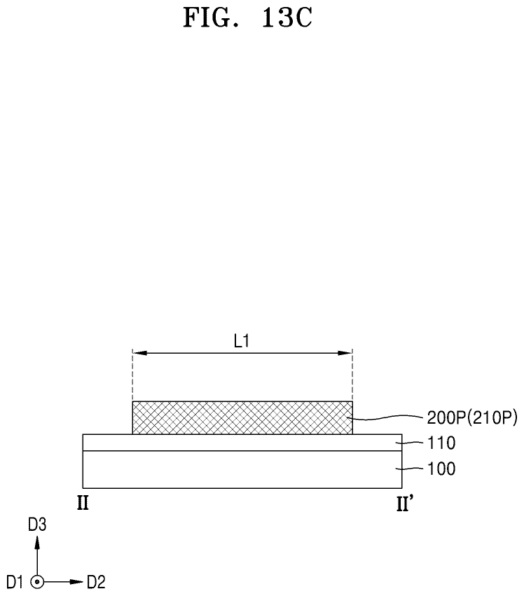

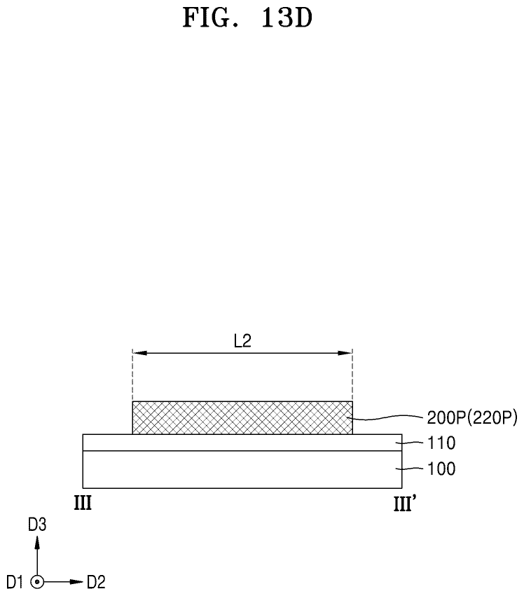

Referring to FIGS. 13A to 13D, the resist patterns 500, the metal oxide pattern 700, the under pattern 320P, the protective pattern 310P, and the etching stop pattern 340P may be removed to expose the top surface of the target pattern 200P. For example, the top surfaces of the first target patterns 210P and the top surface of the second target pattern 220P may be exposed.

The first target patterns 210P may be formed at positions corresponding to the resist patterns 500 in FIGS. 12A and 12C and may be formed in the same shape as or similar shape to the resist patterns 500. The first target patterns 210P may have the same pitch/width/length as or similar pitch/width/length to the resist patterns 500. For example, the length L1 of the first target patterns 210P may be the same as or substantially similar to the length L10 of the resist patterns 500.

The second target pattern 220P may be arranged between the first target patterns 210P. A plurality of second target patterns 220P may be provided. The first target patterns 210P may be alternately arranged with the plurality of second target patterns 220P. Hereinafter, a single second target pattern 220P is described.

The second target pattern 220P may be formed at a position corresponding to the metal oxide pattern 700 in FIGS. 12A and 12C and may be formed in the same shape as or similar shape to the metal oxide pattern 700. The second target pattern 220P may have the same pitch/width/length as or similar pitch/width/length to the metal oxide pattern 700. For example, the length L2 of the second target pattern 220P may be the same as or substantially similar to the length L20 of the metal oxide pattern 700. The length L2 of the second target pattern 220P may be different from the length L1 of the first target patterns 210P. For example, the length L2 of the second target pattern 220P may be greater than the length L1 of the first target patterns 210P.

Unlike FIGS. 12A to 13D, the resist patterns 500 may have a greater etching resistance than the metal oxide pattern 700. In this case, the ends of the metal oxide pattern 700 may be further recessed laterally. In this case, the length L2 of the second target pattern 220P may be less than the length L1 of the first target patterns 210P.

The target pattern 200P may be one of the plurality of target patterns 200P. The plurality of target patterns 200P may be spaced apart from each other in the first direction D1. The plurality of target patterns 200P may have a third pitch P3. The third pitch P3 may be less than the first pitch P1 of the resist patterns 500 of FIG. 1B. The third pitch P3 may be a relatively fine pitch. For example, the third pitch P3 may be between about 30 nm and about 400 nm. Each of the plurality of target patterns 200P may have a bar shape. The plurality of target patterns 200P may extend in a direction parallel to the second direction D2.

The target patterns 200P may further include metal. The metal may include any one of the first metal included in the metal oxide of resist patterns 500 of FIG. 4B or the second metal included in the metal oxide pattern 700. The concentration of the first metal and the concentration of the second metal in the target patterns 200P are as described with reference to FIGS. 8A to 8D.

The target patterns 200P may be components of the semiconductor device.

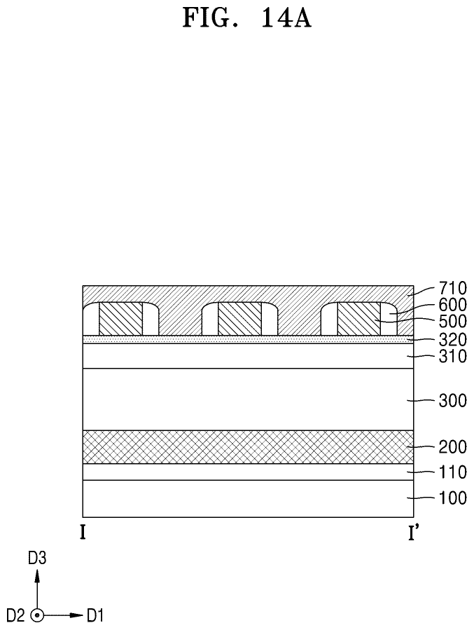

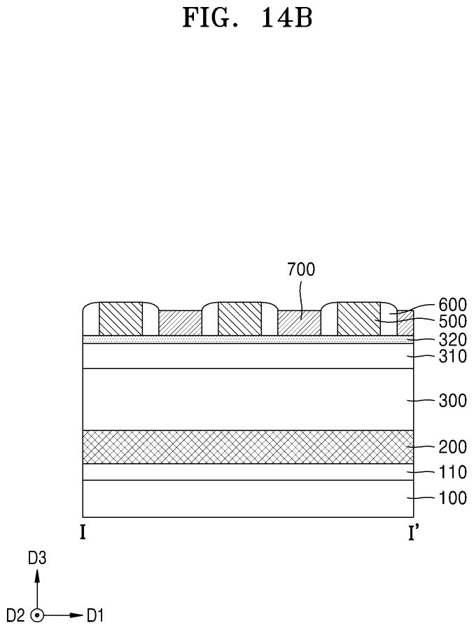

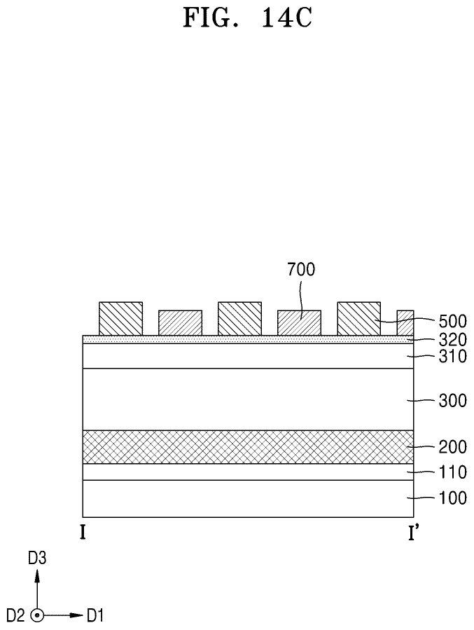

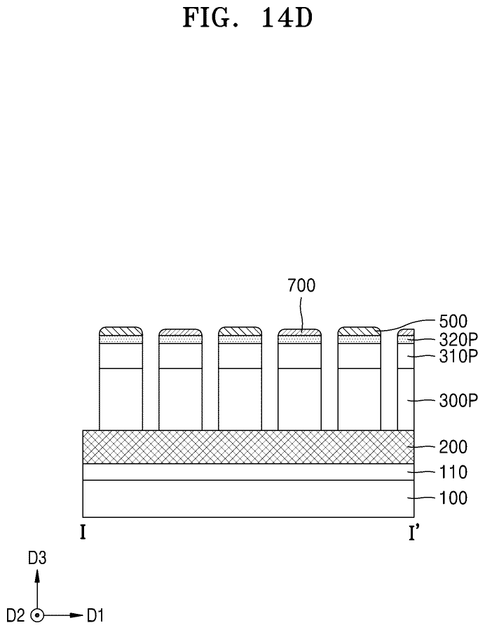

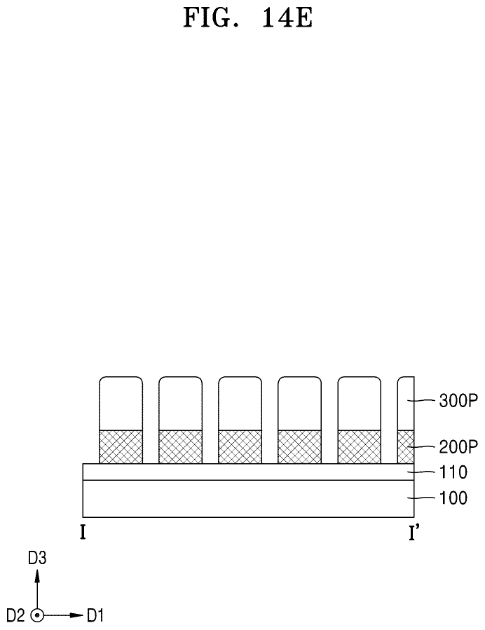

FIGS. 14A to 14E are diagrams illustrating a method of forming a pattern, according to an example embodiment. Hereinafter, descriptions that are the same as or substantially similar to those given above may be omitted.

Referring to FIG. 14A, the substrate 100, on which the lower layer 110, the etching target layer 200, the mask layer 300, the protective layer 310, the under layer 320, and the resist patterns 500 are stacked, may be prepared.

The mask layer 300 may be formed on the etching target layer 200. The mask layer 300 may be arranged between the etching target layer 200 and the under layer 320. The mask layer 300 may include an amorphous carbon layer (ACL). The mask layer 300 may include a spin on hardmask (SOH) film, a spin-on carbon (SOC) film, or an amorphous carbon film. The mask layer 300 may be a single layer or a multilayer. Although not shown, the etching stop layer 340 of FIGS. 9A to 9D may be further arranged between the mask layer 300 and the protective layer 310.

The resist patterns 500 and the spacer patterns 600 may be formed on the under layer 320 by the methods described with reference to FIGS. 1A to 2D.

The metal oxide layer 710 may be formed on the substrate 100 to cover the resist patterns 500 and the spacer patterns 600. The metal oxide layer 710 may be formed by a sol-gel method. For example, the precursor in a solution state, sol state, or gel state may be coated on the resist patterns 500 and the spacer patterns 600 to form the preliminary metal oxide layer 710P as shown in FIGS. 3A and 3B. The preliminary metal oxide layer 710P may be solidified by the first heat treatment process, as shown in FIGS. 3B and 3C, to form the metal oxide layer 710.

Referring to FIG. 14B, a portion of the metal oxide layer 710 may be removed to form the metal oxide pattern 700. The spacer patterns 600 and the resist patterns 500 may be exposed.

Referring to FIG. 14C, the exposed spacer patterns 600 may be removed by an etching process to expose the under layer 320. The etching of the spacer patterns 600 may be performed by the method described with reference to FIGS. 6A and 6B or FIGS. 11A to 11C.

Referring to FIGS. 14D and 14E in turn, the etching process using the resist patterns 500 and the metal oxide pattern 700 as an etching mask may be performed to etch the under layer 320, the protective layer 310, and the mask layer 300. Accordingly, after the etching process is completed, the under layer 320 and the protective layer 310 may form the under pattern 320P and the protective pattern 310P, respectively. A portion of the mask layer 300 exposed by the protective pattern 310P may be removed to form the mask pattern 300P. The mask pattern 300P may be disposed on the first portion and the second portion of the etching target layer 200 and may expose the top surface of the third portion of the etching target layer 200. The exposed third portion of the etching target layer 200 may then be etched to form the target pattern 200P as shown in FIG. 14E. During the etching process, the resist patterns 500, the metal oxide pattern 700, and the under pattern 320P may be further removed. During the etching process, the upper portion of the mask pattern 300P may be recessed. However, the lower portion of the mask pattern 300P may remain unremoved. The remaining mask pattern 300P may be used as an etch mask. The first portion and the second portion of the etching target layer 200 may not be exposed to the etching process by the mask pattern 300P. After the etching process, the first portion and the second portion of the etching target layer 200 may form the target pattern 200P.

Referring again to FIG. 8B or FIG. 13B, the mask pattern 300P may be removed to expose the top surface of the target pattern 200P. The removing of the mask pattern 300P may be performed by ashing and stripping processes. Accordingly, the forming of the target pattern 200P may be completed.

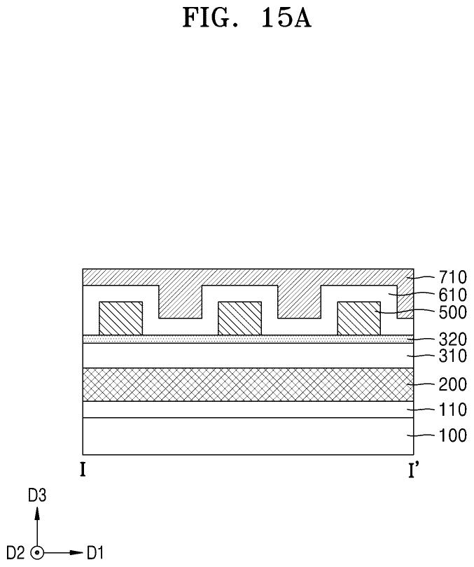

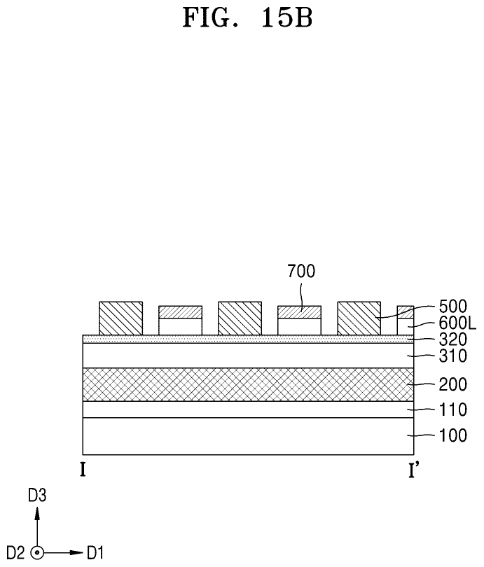

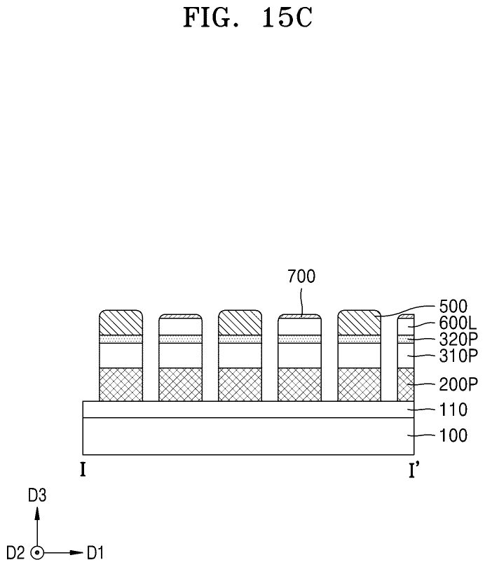

FIGS. 15A to 15C are diagrams illustrating a method of forming a pattern, according to an example embodiment.

Referring to FIG. 15A, the substrate 100, on which the lower layer 110, the etching target layer 200, the protective layer 310, the under layer 320, and the resist patterns 500 are stacked, may be prepared. The spacer film 610 may be formed on the under layer 320 to cover the top surfaces and sidewalls of the resist patterns 500. The spacer film 610 may include first portions, second portions, and a third portion. The first portions of the spacer film 610 may be provided on top surfaces of the resist patterns 500. The second portions of the spacer film 610 may be provided on sidewalls of the resist patterns 500. The third portion of the spacer film 610 may cover the under layer 320.

The metal oxide layer 710 may be formed on the resist patterns 500 to cover the spacer film 610. The metal oxide layer 710 may be formed by the method described with reference to FIGS. 3A to 3C.

Referring to FIG. 15B, a portion of the metal oxide layer 710 may be removed to form the metal oxide pattern 700. The metal oxide layer 710 may be removed by an etch-back process or a CMP process described with reference to FIG. 4B.

The first portions and the second portions of the spacer film 610 may be removed to expose the top surfaces of the resist patterns 500, the sidewalls of the resist patterns 500, and the partial top surface of the under layer 320. The spacer film 610 may be removed by an etching process. The etching process may be performed by a dry etching process or a wet etching process using, for example, a fluorine gas. The first portions or the second portions of the spacer film 610 may be removed by a single process with the removing process of the metal oxide layer 710. In some example embodiments, the second portions of the spacer film 610 may be removed by a process separate from the removing of the metal oxide layer 710.

The third portion of the spacer film 610 may not be exposed by the etching process to the metal oxide pattern 700. After the etching process is completed, the third portion of the spacer film 610 may form a lower spacer pattern 600L. The lower spacer pattern 600L may expose the under layer 320. The lower spacer pattern 600L may be arranged between the etching target layer 200 and the metal oxide pattern 700. For example, the lower spacer pattern 600L may be arranged between the under layer 320 and the metal oxide pattern 700. The lower spacer pattern 600L may be laterally spaced apart from the resist patterns 500.

Referring to FIG. 15C, the etching process using the resist patterns 500 and the metal oxide pattern 700 as an etching mask may be performed to etch the under layer 320, the protective layer 310, and the etching target layer 200. Accordingly, the under pattern 320P, the protective pattern 310P, and the target pattern 200P may be formed. The top surface of the lower layer 110 may be exposed.

Referring again to FIG. 8B or FIG. 13B, the resist patterns 500, the metal oxide pattern 700, the lower spacer pattern 600L, the under pattern 320P, and the protective pattern 310P may be removed to expose the top surface of the target pattern 200P.

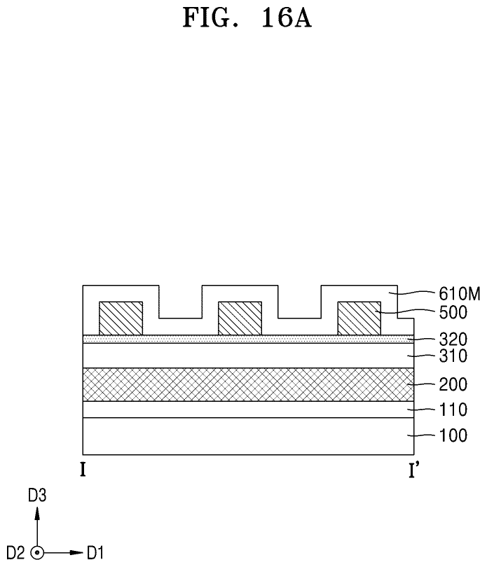

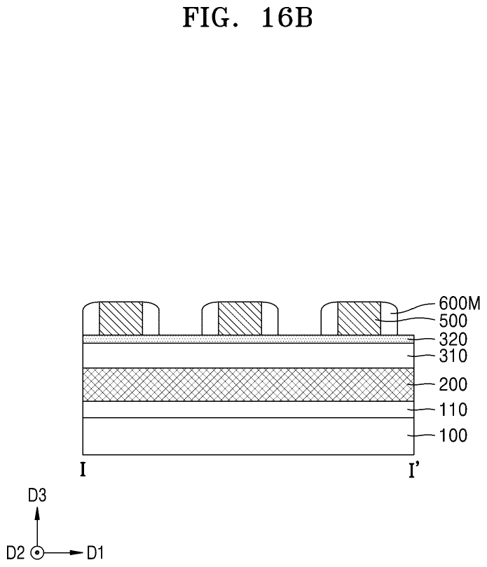

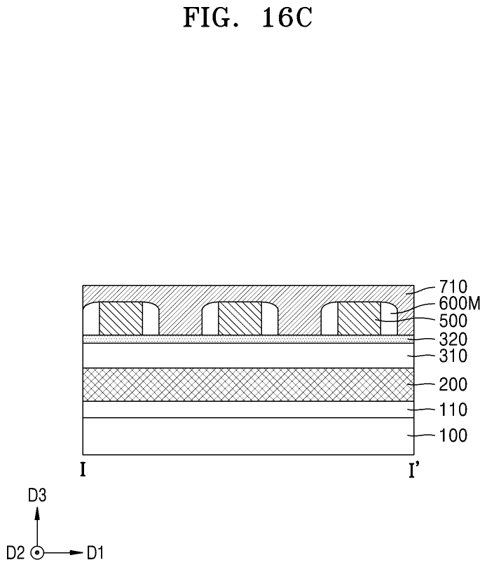

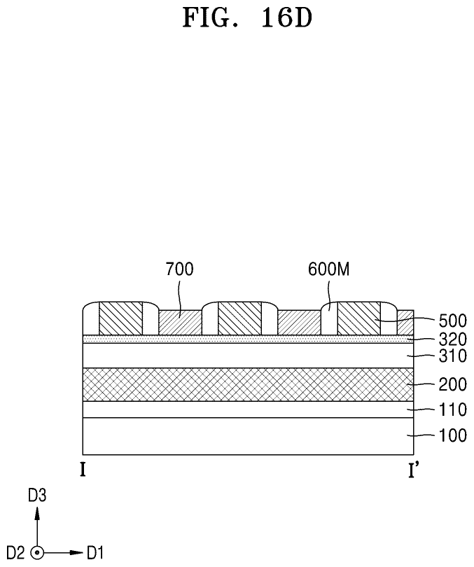

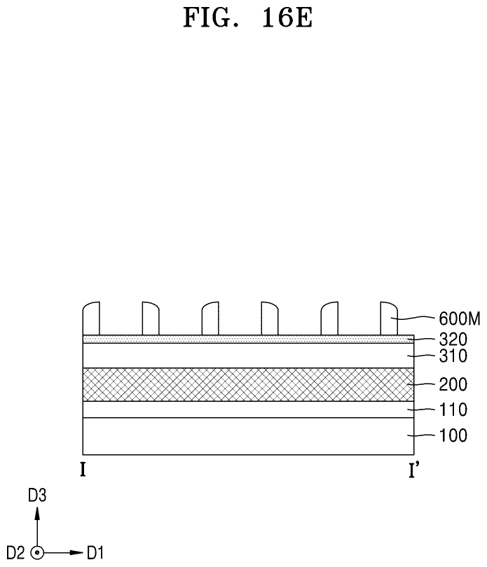

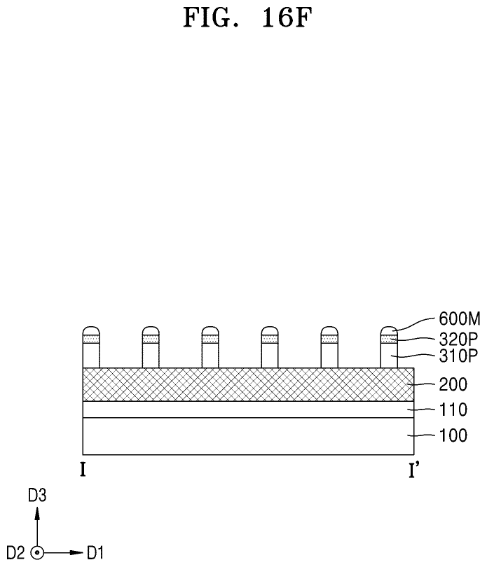

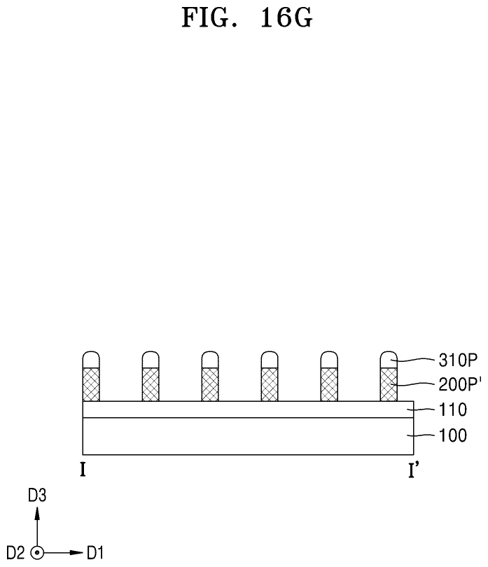

FIGS. 16A to 16G are diagrams illustrating a method of forming a pattern, according to an example embodiment.

Referring to FIG. 16A, the substrate 100, on which the lower layer 110, the etching target layer 200, the protective layer 310, the under layer 320, and the resist patterns 500 are stacked, may be prepared. A first metal spacer film 610M may be formed on the substrate 100 to cover the top surfaces and sidewalls of the resist patterns 500. The first metal spacer film 610M may extend onto the top surface of the protective layer 310 (more specifically, onto the top surface of the under layer 320). The first metal spacer film 610M may be formed by a deposition process, such as an ALD process. The first metal spacer film 610M may include tungsten (W), tungsten nitride (WNx), titanium (Ti), titanium nitride (TiNx), molybdenum (Mo), ruthenium (Ru), and/or a combination thereof. (x is a positive rational number)

Referring to FIG. 16B, the etching process may be performed on the first metal spacer film 610M to form the metal spacer patterns 600M. The etching process may include a dry etching process using an inert gas. The top surfaces of the resist patterns 500 and the top surface of the under layer 320 may be exposed by the etching process. The metal spacer patterns 600M may cover sidewalls of the resist patterns 500.

The metal included in the metal spacer patterns 600M may be different from the first metal included in the metal oxide of the resist patterns 500 and the second metal included in the metal oxide pattern 700. The metal spacer patterns 600M may be free of oxygen. An oxygen content in the metal spacer patterns 600M may be less than an oxygen content in the resist patterns 500. That an oxygen content in the metal spacer patterns 600M is less than an oxygen content in the resist patterns 500 may include that an oxygen content in the metal spacer patterns 600M is substantially zero. A metal content in the metal spacer patterns 600M may be greater than that in the resist patterns 500.

Referring to FIG. 16C, the metal oxide layer 710 may be formed on top surfaces of the resist patterns 500, outer walls of the metal spacer patterns 600M, and top surfaces of the protective layer 310 (more specifically, the top surface of the under layer 320). The metal oxide layer 710 may be formed by the method described with reference to FIGS. 3A to 3C.

Referring to FIG. 16D, the metal oxide layer 710 may be recessed by an etching process to expose the top surfaces of the resist patterns 500 and the metal spacer patterns 600M. The etching process of the metal oxide layer 710 may be performed by the method described with reference to FIGS. 4A and 4B. The top surfaces of the metal oxide layer 710 may be provided at the same level as or lower level than the top surfaces of the resist patterns 500.

An oxygen content in the metal oxide pattern 700 may be greater than that in the metal spacer patterns 600M. A metal content in the metal oxide pattern 700 may be less than that in the metal spacer patterns 600M.

Referring to FIG. 16E, the resist patterns 500 and the metal oxide pattern 700 may be removed by an etching process. Accordingly, the top surface of the protective layer 310 and the sidewalls of the metal spacer patterns 600M may be exposed. The etching of the resist patterns 500 and the metal oxide pattern 700 may include wet etching, dry etching, or a combination thereof. Because the metal spacer patterns 600M include a metal that is different from the resist patterns 500 and the metal oxide pattern 700, in the etching process, the metal spacer pattern 600M may have etching selectivity with respect to the resist patterns 500 and the metal oxide pattern 700. After the etching process is completed, the metal spacer patterns 600M may remain.

Referring to FIGS. 16F and 16G in turn, the etching process using the metal spacer patterns 600M as an etching mask may be performed to etch the under layer 320 and the protective layer 310. Accordingly, the under pattern 320P and the protective pattern 310P may be formed, and the top surface of the etching target layer 200 may be exposed. During the etching process, the metal spacer patterns 600M may be recessed, thereby reducing the thickness of the metal spacer patterns 600M.

Thereafter, the exposed portion of the etching target layer 200 may be etched to form a target pattern 200P′ as shown in FIG. 16G. In the etching process, the metal spacer patterns 600M, the under pattern 320P, and the protective pattern 310P may be used as an etching mask. The metal spacer patterns 600M and the under pattern 320P may be removed in the etching process of the etching target layer 200. During the etching process, at least a portion of the protective layer 310 may be recessed. However, after the etching process is completed, the lower portion of the protective layer 310 may remain. The target pattern 200P′ may expose the top surface of the lower layer 110. The etching process may include dry etching or wet etching.

The target pattern 200P′ of FIG. 16G may be formed at the same pitch/width/length as or similar pitch/width/length to the position corresponding to the metal spacer patterns 600M of FIGS. 16E and 16F. The target pattern 200P′ may have the same shape as or similar shape to the metal spacer patterns 600M.

Referring to FIG. 16H, the protective pattern 310P may be removed to expose the top surface of the target pattern 200P′.

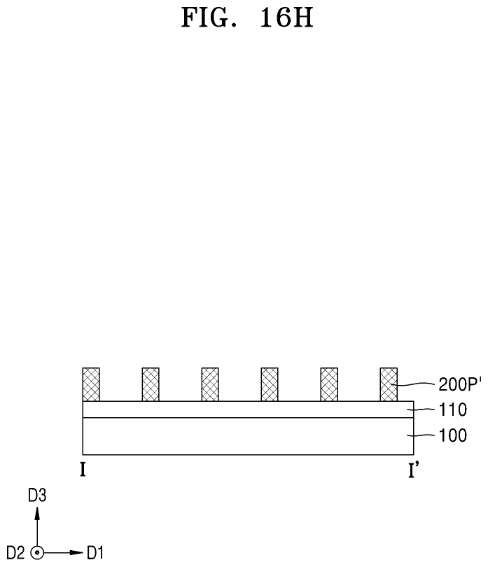

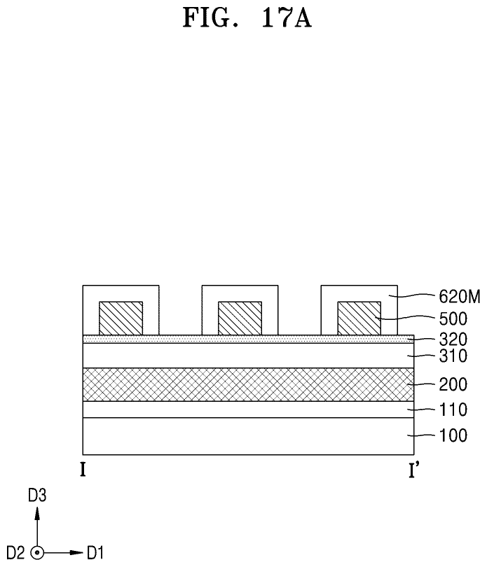

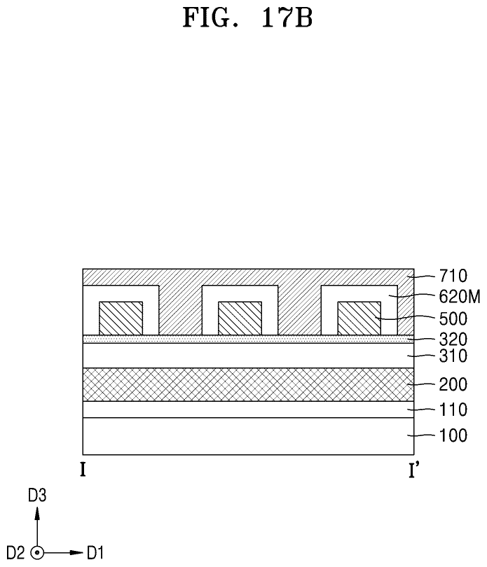

FIGS. 17A and 17B are diagrams illustrating a method of forming a pattern, according to an example embodiment.

Referring to FIG. 17A, the lower layer 110, the etching target layer 200, the protective layer 310, the under layer 320, and the resist patterns 500 may be formed on the substrate 100. The second metal spacer films 620M may each be formed on the resist patterns 500, respectively. The second metal spacer films 620M may cover the sidewalls and top surfaces of the resist patterns 500. Unlike the first metal spacer film 610M of FIG. 16A, the second metal spacer films 620M may not extend onto the top surface of the under layer 320. The second metal spacer films 620M may be formed by an area selective deposition (ASD) process. The resist patterns 500 may include metal oxide, while the under layer 320 may not include a metal material. Accordingly, the second metal spacer films 620M may be selectively formed on the resist patterns 500. The second metal spacer films 620M may include the same material as those of the metal spacer patterns 600M described with reference to FIG. 6B. For example, the second metal spacer films 620M may be free of oxygen. An oxygen content in the second metal spacer films 620M may be less than that in the resist patterns 500. A metal content in the second metal spacer films 620M may be greater than that in the resist patterns 500. The second metal spacer films 620M may include, for example, tungsten (W), tungsten nitride (WNx), titanium (Ti), titanium nitride (TiNx), molybdenum (Mo), ruthenium (Ru), and/or a combination thereof. (x is a positive rational number)

Referring to FIG. 17B, the metal oxide layer 710 may be formed on the second metal spacer films 620M and the under layer 320. The metal oxide layer 710 may be formed by the method described with reference to FIGS. 3A to 3C. An oxygen content in the metal oxide layer 710 may be greater than that in the second metal spacer films 620M. A metal content in the metal oxide layer 710 may be less than that in the second metal spacer films 620M.

Referring again to FIG. 16D in conjunction with FIG. 17B, a portion of the metal oxide layer 710 may be removed to form the metal oxide pattern 700 and expose the second metal spacer films 620M. The metal oxide layer 710 may be removed by an etch-back process or a CMP process. Portions of the second metal spacer films 620M on the top surfaces of the resist patterns 500 may be removed to form the metal spacer patterns 600M. The metal spacer patterns 600M may be disposed on the sidewalls of the resist patterns 500 to expose the top surfaces of the resist patterns 500. The second metal spacer films 620M may be removed by a single process or a separate process together with the removal of the metal oxide layer 710.

The target pattern 200P′ may then be formed by the methods described with reference to FIGS. 16E to 16G.

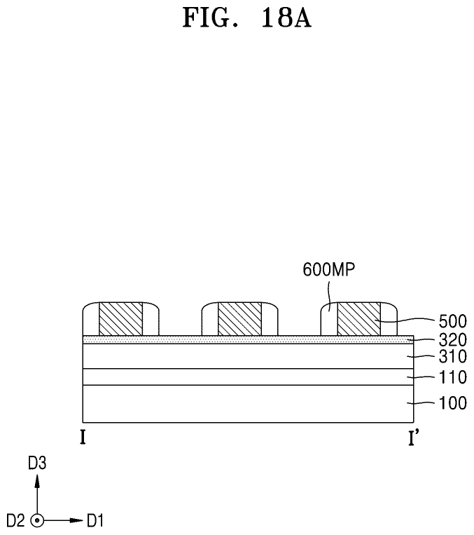

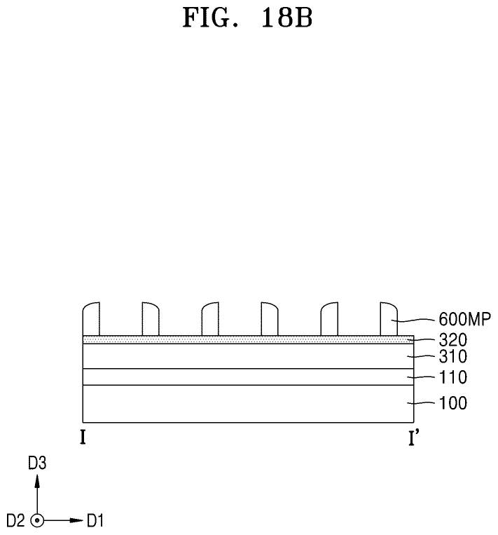

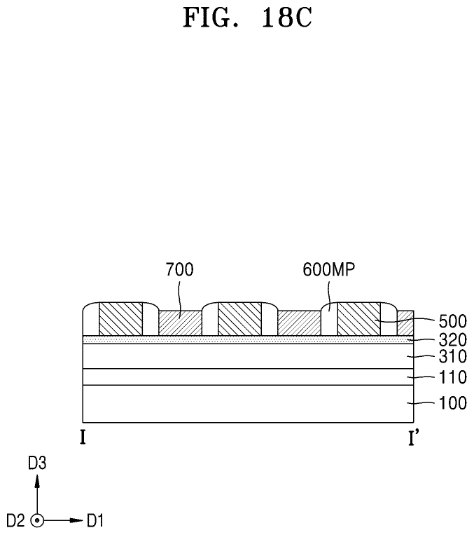

FIGS. 18A and 18B are diagrams illustrating a method of forming a pattern, according to an example embodiment.

Referring to FIG. 18A, the lower layer 110, the protective layer 310, the under layer 320, the resist patterns 500, and metal patterns 600MP may be formed on the substrate 100. The properties of the metal patterns 600MP may be the same as or substantially similar to those of the metal spacer patterns 600M of FIGS. 16A and 16B. The placement, material, and formation method of the metal patterns 600MP may be the same as or substantially similar to those of the metal spacer patterns 600M of FIGS. 15A and 15B. For example, the metal patterns 600MP may be free of oxygen. An oxygen content in the metal patterns 600MP may be less than an oxygen content in the resist patterns 500. A metal content in the metal patterns 600MP may be greater than that in the resist patterns 500. However, the etching target layer 200 of FIG. 15A may not be formed.

Referring to FIG. 18B, the resist patterns 500 may be removed by an etch process. In the etching process, the metal patterns 600MP may have etching selectivity with respect to the resist patterns 500. After the etching process is completed, the top surface of the under layer 320 and the sidewalls of the metal patterns 600MP may be exposed.

The metal patterns 600MP may include a component of the semiconductor device. For example, the metal patterns 600MP may function as an electrode or wiring. For example, the metal patterns 600MP may function as a gate electrode, a word line, or a bit line, but are not limited thereto.

FIG. 18C is a diagram illustrating a method of forming a pattern, according to an example embodiment.

Referring to FIG. 18C, the lower layer 110, the protective layer 310, the under layer 320, the resist patterns 500, the metal oxide pattern 700, and the metal patterns 600MP may be formed on the substrate 100. The etching target layer 200 of FIG. 15A may not be formed. The metal patterns 600MP may be the same as or substantially similar to those described with reference to FIG. 18A.

The metal oxide pattern 700 may be formed on the under layer 320 to cover the sidewalls of the metal patterns 600MP. The forming of the metal oxide pattern 700 may include forming the metal oxide layer 710 by coating with the precursor in a solution, sol, or gel state, and recessing the metal oxide layer 710. An oxygen content in the metal patterns 600MP may be less than that in the metal oxide pattern 700. A metal content in the metal patterns 600MP may be greater than that in the metal oxide pattern 700.

Referring again to FIG. 18C, the resist patterns 500 and the metal oxide pattern 700 may be removed by an etching process to expose the top surface of the under layer 320 and the sidewalls of the metal patterns 600MP. In the etching process, the metal patterns 600MP may have etching selectivity for the resist patterns 500 and the metal oxide pattern 700.

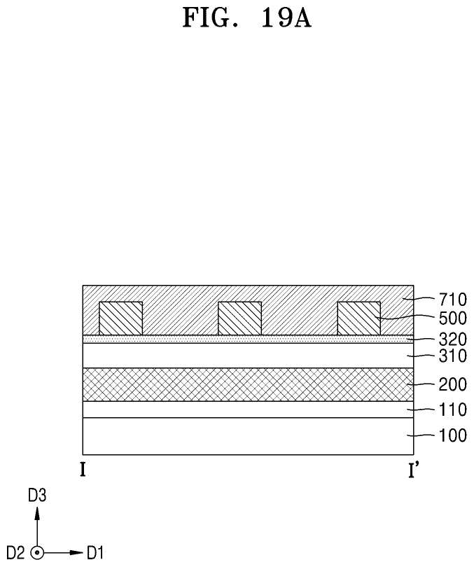

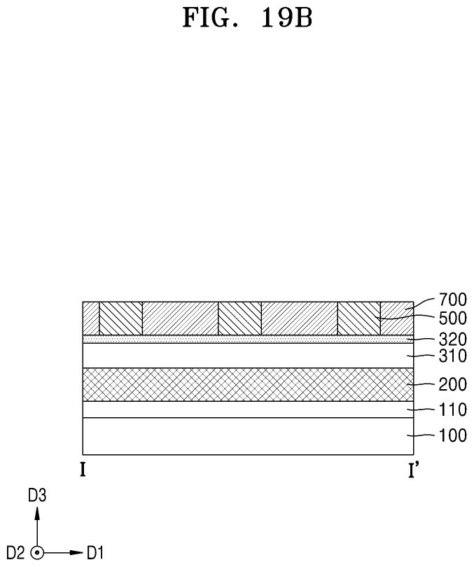

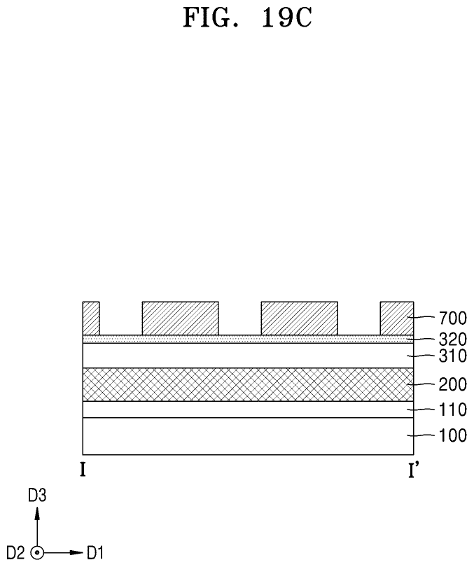

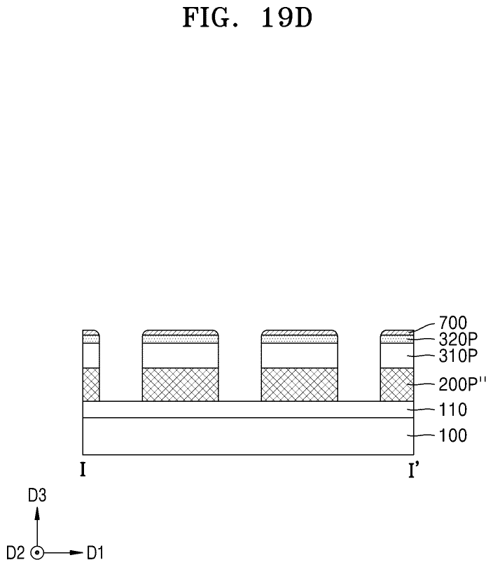

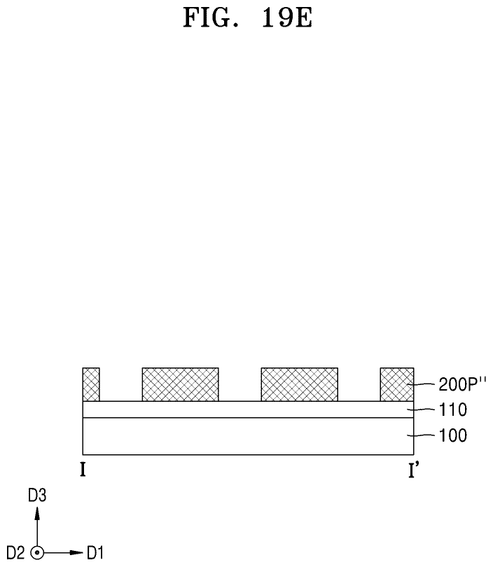

FIGS. 19A to 19E are diagrams illustrating a method of forming a pattern, according to an example embodiment.

Referring to FIG. 19A, the substrate 100, where the lower layer 110, the etching target layer 200, the protective layer 310, the under layer 320, and the resist patterns 500 are stacked, may be prepared. The metal oxide layer 710 may be formed on the resist patterns 500 and the under layer 320. The metal oxide layer 710 may be in physical contact with the top surfaces and sidewalls of the resist patterns 500. The metal oxide layer 710 may be formed by the methods described with reference to FIGS. 3A to 3C.

Referring to FIG. 19B, a portion of the metal oxide layer 710 may be removed to form the metal oxide pattern 700. The metal oxide pattern 700 may expose top surfaces of the resist patterns 500. The removing of the metal oxide layer 710 may be performed by an etch-back process or a CMP process. The top surface of the metal oxide pattern 700 may be provided at the same level as or as a lower level than the resist patterns 500.

Referring to FIG. 19C, the resist patterns 500 may be removed by an etch process. The etching process may include a wet etching process. According to an example embodiment, the metal oxide pattern 700 may include a material that is different from the resist patterns 500 and may have an etching resistance greater than that in the resist patterns 500. After the resist patterns 500 are removed, the metal oxide pattern 700 may expose the under layer 320.

Referring to FIG. 19D, the etching process using the metal oxide pattern 700 as an etching mask may be performed to etch the under layer 320, the protective layer 310, and the etching target layer 200. Accordingly, the under pattern 320P, the protective pattern 310P, and a target pattern 200P″ may be formed. The target pattern 200P′′ may expose the lower layer 110.

Referring to FIG. 19E, the metal oxide pattern 700, the under pattern 320P, and the protective pattern 310P may be removed to expose the top surface of the target pattern 200P″.

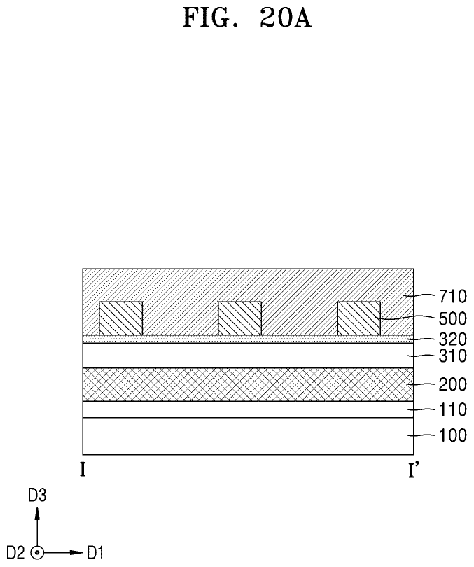

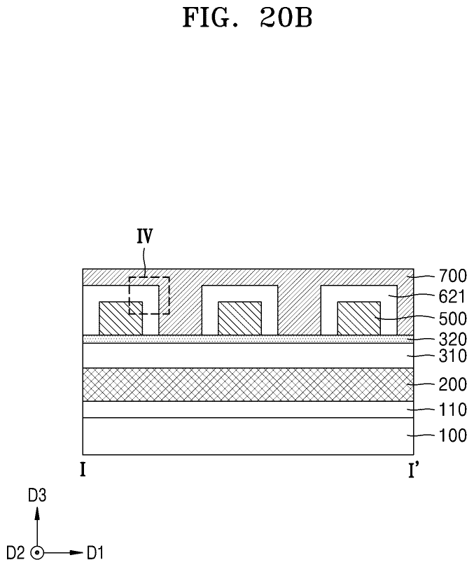

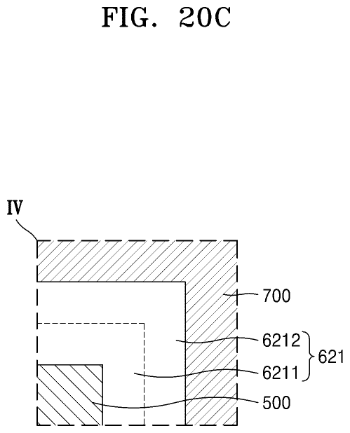

FIGS. 20A to 20C are diagrams illustrating a method of forming a pattern, according to an example embodiment.

Referring to FIG. 20A, the lower layer 110, the etching target layer 200, the protective layer 310, the under layer 320, and the resist patterns 500 may be formed on the substrate 100. The metal oxide layer 710 may be formed on the resist patterns 500 and the under layer 320. The metal oxide layer 710 may be in physical contact with the top surfaces and sidewalls of the resist patterns 500. The metal oxide layer 710 may be formed by the method described with reference to FIGS. 3A to 3C.

Referring to FIG. 20B, a heat treatment process may be performed on the metal oxide layer 710 and the resist patterns 500. The heat treatment process may cause an oxidation reaction at the interface between the metal oxide layer 710 and the resist patterns 500. Accordingly, an oxide spacer film 621 may be formed between the metal oxide layer 710 and the resist patterns 500. The oxide spacer film 621 may not extend onto some portions of the top surface of the under layer 320. The heat treatment process may be performed at a temperature of about 50 °C to about 200 °C. The heat treatment process may correspond to the first heat treatment process of FIG. 3B. In some example embodiments, the heat treatment process may be performed by a process separate from the first heat treatment process of FIG. 3B. Hereinafter, the forming of the oxide spacer film 621 is described in more detail.

FIG. 20C is an enlarged view of region IV of FIG. 20B. In describing FIG. 20C, the single resist pattern 500 is described.

Referring to FIGS. 20B and 20C, the forming of the oxide spacer film 621 may include oxidizing a portion of the resist pattern 500 and oxidizing a portion of the metal oxide layer 710. The oxide spacer film 621 may include a first portion 6211 and a second portion 6212. A portion of the resist pattern 500 may be oxidized to form the first portion 6211 of the oxide spacer film 621. The first portion 6211 of the oxide spacer film 621 may be arranged between the second portion 6212 of the oxide spacer film 621 and the resist pattern 500 corresponding thereto. The first portion 6211 of the oxide spacer film 621 may include the same metal material as the metal oxide included in the resist pattern 500. However, an oxygen content in the first portion 6211 of the oxide spacer film 621 may be greater than that in the resist pattern 500.

A portion of the metal oxide layer 710 may be oxidized to form the second portion 6212 of the oxide spacer film 621. The second portion 6212 of the oxide spacer film 621 may be arranged between the first portion 6211 of the oxide spacer film 621 and the metal oxide layer 710. The second portion 6212 of the oxide spacer film 621 may include the same metal material as the metal oxide included in the metal oxide layer 710. However, an oxygen content in the second portion 6212 of the oxide spacer film 621 may be greater than that in the metal oxide layer 710.

Referring again to FIGS. 4A and 4B, a portion of the metal oxide layer 710 may be removed to expose the oxide spacer film 621. The portion of the exposed oxide spacer film 621 may be removed to form the spacer patterns 600. For example, the oxide spacer film 621 on the top surface of the resist pattern 500 may be removed. The spacer patterns 600 may be formed by a single process or a separate process together with the removing of the metal oxide layer 710. The remaining metal oxide layer 710 may form the metal oxide pattern 700.

Thereafter, the target pattern 200P may be formed by the methods described with reference to FIGS. 5A to 8D.

In some example embodiments, after the oxide spacer film 621 of FIG. 20B is formed, a portion of the metal oxide layer 710 may be removed to expose the oxide spacer film 621 as described with reference to FIGS. 9A to 9D. A portion of the exposed oxide spacer film 621 may be removed to form the spacer patterns 600. Then, the target pattern 200P may be formed by the methods described with reference to FIGS. 9A to 13D.

At least two of the above example embodiments may be combined with each other. For example, in the method of forming a pattern, according to an example embodiment of FIG. 1A to FIG. 8D, an example embodiment of FIG. 9A to FIG. 13D, an example embodiment of FIG. 15A to FIG. 15C, an example embodiment of FIGS. 16A to 16G, an example embodiment of FIGS. 17A and 17B, an example embodiment of FIGS. 19A to 19E, or an example embodiment of FIGS. 20A and 20B, the mask layer 300 may be further formed as described with reference to FIGS. 14A to 14E. In this case, the etching target layer 200 may be etched using the mask layer 300. Example embodiments are not limited thereto and may be variously combined.

According to some example embodiments, the spacers may include at least one of the spacer film 610 of FIG. 1C, the spacer patterns 600 of FIGS. 2A and 2B, the spacer patterns 600 of FIGS. 9A and 9B, the spacers patterns 600 of FIG. 14A, the spacer film 510 of FIG. 15A, the lower spacer pattern 600L of FIG. 15B, the first metal spacer film 610M of FIG. 16A, the metal spacer patterns 600M of FIG. 16B, the second metal spacer films 620M of FIG. 17A, the metal patterns 600MP of FIG. 18C, or the oxide spacer film 621 of FIG. 20B.

According to some example embodiments of the inventive concepts, the resist pattern may include metal oxide. The metal oxide layer may be formed on the resist patterns. The forming of the metal oxide layer may include forming metal oxide by coating with the precursor in a solution, sol, or gel state, and recessing the metal oxide layer. According to such example embodiments, efficiency and/or productivity of the patterning process may be improved.

While the inventive concepts have been particularly shown and described with reference to some example embodiments thereof, it will be understood that various changes in form and details may be made therein without departing from the spirit and scope of the following claims.

What is claimed is:

1. A method of manufacturing a semiconductor device, the method comprising:
forming resist patterns on a substrate;
coating a precursor on the resist patterns to form a preliminary metal oxide layer, the precursor being in a state of one of a solution, a sol, or a gel;
solidifying the preliminary metal oxide layer to form a metal oxide layer; and
recessing the metal oxide layer to form a metal oxide pattern exposing top surfaces of the resist patterns,
wherein the resist patterns comprise a metal oxide,
an oxygen content in the metal oxide pattern is greater than an oxygen content in the resist patterns, and
the metal oxide pattern is arranged between the resist patterns.

2. The method of claim 1, wherein
the precursor comprises metal oxide and a solvent, and
the solidifying of the preliminary metal oxide layer comprises performing a first heat treatment process on the preliminary metal oxide layer to remove the solvent in the preliminary metal oxide layer.

3. The method of claim 2, further comprising:
performing a second heat treatment process using a hydrogen-containing gas on the metal oxide pattern,
wherein an oxygen content in the metal oxide pattern after the second heat treatment process is less than an oxygen content in the metal oxide pattern before the second heat treatment process.

4. The method of claim 3, wherein the second heat treatment process is performed at a greater temperature than the first heat treatment process.

5. The method of claim 3, wherein an oxygen content in the metal oxide pattern after the second heat treatment process is greater than an oxygen content in the resist patterns.

6. The method of claim 1, further comprising:
forming an etching target layer on the substrate so that the forming of the resist patterns forms the resist patterns on the etching target layer; and
performing an etching process using the resist patterns and the metal oxide pattern as an etching mask.

7. The method of claim 6, wherein
the performing of the etching process comprises forming a target pattern by removing a portion of the etching target layer,
the metal oxide of the resist patterns comprises a first metal, and
a concentration of the first metal in the target pattern is 1E11/cm³ or less.

8. The method of claim 1, further comprising forming:
a spacer pattern on sidewalls of the resist patterns to be between a corresponding one of the resist patterns and the metal oxide layer.

9. A method of forming a pattern, the method comprising:
forming a resist pattern comprising a metal oxide, on a substrate;
forming spacers on sidewalls of the resist pattern;
forming a preliminary metal oxide layer to cover the spacers by coating the resist pattern and the spacers with a precursor, the precursor being in a state of one of a solution, a sol, or a gel;
solidifying the preliminary metal oxide layer to form a metal oxide layer; and
recessing the metal oxide layer to form a metal oxide pattern exposing a top surface of the resist pattern,
wherein the metal oxide pattern is laterally spaced apart from the resist pattern, and
a metal content in the metal oxide pattern is less than a metal content in the resist pattern.

10. The method of claim 9, wherein
the spacers comprise a metal material, and
a metal content in the spacers is greater than a metal content in the metal oxide pattern and a metal content in the resist pattern.

11. The method of claim 9, wherein the spacers comprise a metal material, and
the spacers comprise a first metal that is different from a second metal in the metal oxide pattern and a third metal in the resist pattern.

12. The method of claim 9, wherein the spacers comprise silicon oxide.

13. The method of claim 9, further comprising:
forming an etching target layer on the substrate;
forming an upper layer on the etching target layer, so that the forming of the resist pattern forms the resist pattern on the etching target layer;
removing the spacers to expose the upper layer; and
performing an etching process using the resist pattern and the metal oxide pattern as an etching mask to remove a portion of the upper layer.

14. The method of claim 9, further comprising:
forming an etching target layer and an upper layer in sequence on the substrate, so that the forming of the resist pattern forms the resist pattern on the upper layer;
removing the resist pattern and the metal oxide pattern to expose sidewalls of the spacers and a top surface of the upper layer; and
performing an etching process using the spacers as an etching mask.

15. A method of forming a pattern, the method comprising:
forming an etching target layer on a substrate;
forming an upper layer on the etching target layer;
forming resist patterns including a metal oxide, on the upper layer;
performing a coating process using a precursor in a solution, sol, or gel state to form a preliminary metal oxide layer between the resist patterns;
solidifying the preliminary metal oxide layer to form a metal oxide layer;
removing the metal oxide layer on top surfaces of the resist patterns to form a metal oxide pattern; and
performing an etching process using the resist patterns and the metal oxide pattern as an etching mask.

16. The method of claim 15, wherein
an oxygen content in the metal oxide pattern is greater than an oxygen content in the resist patterns, and
a metal content in the metal oxide pattern is less than a metal content in the resist patterns.

17. The method of claim 15, wherein the solidifying of the preliminary metal oxide layer comprises performing a heat treatment process on the preliminary metal oxide layer to remove a solvent in the preliminary metal oxide layer.

18. The method of claim 15, wherein
the performing of the etching process comprises removing a portion of the etching target layer to form a target pattern,
the metal oxide pattern comprises a metal, and
a concentration of the metal in the target pattern is 1E11/cm³ or less.

19. The method of claim 15, wherein
the performing of the etching process comprises removing a portion of the etching target layer to form a target pattern,
the target pattern comprises first target patterns comprising first portions of the etching target layer overlapping the resist patterns from a plan view, and a second target pattern comprising a second portion of the etching target layer overlapping the metal oxide pattern from a plan view, and
a length of each of the first target patterns is different from a length of the second target pattern.

20. The method of claim 15, wherein a thickness of the metal oxide pattern is less than a thickness of each of the resist patterns, and an aspect ratio of each of the resist patterns is 0.5 to 3.
